(19) United States
(12) Patent Application Publication
(10) Pub. No.: US 2026/0136938 A1
(43) Pub. Date: May 14, 2026

(54) SEMICONDUCTOR CHIP INCLUDING CRACK PROPAGATION PREVENTION STRUCTURE

(71) Applicant: SAMSUNG ELECTRONICS CO., LTD., Suwon-si (KR)

(72) Inventors: Hyoungjin Bae, Suwon-si (KR); Jungmin Ko, Suwon-si (KR)

(73) Assignee: SAMSUNG ELECTRONICS CO., LTD., Suwon-si (KR)

(21) Appl. No.: 19/382,877

(22) Filed: Nov. 7, 2025

(30) Foreign Application Priority Data
Nov. 12, 2024 (KR) 10-2024-0160493

(51) Int. Cl. H01L 23/00; H01L 23/48; H01L 23/522; H01L 23/528; H01L 23/58

(52) U.S. Cl. CPC H10W 42/121; H10W 20/20; H10W 20/42; H10W 20/43; H10W 42/00

(57) ABSTRACT

A semiconductor chip includes a substrate, a device interlayer insulating layer, a wiring layer on the device interlayer insulating layer and including an inner lower insulating stack and an outer lower insulating stack, an upper insulating stack on the wiring layer and including upper insulating layers, a first crack propagation prevention structure on the device interlayer insulating layer between a first insulating layer side surface and a second insulating layer side surface, the first and second insulating layer side surfaces being partially included in the upper insulating stack, and a first blocking trench between the first crack propagation prevention structure and the first insulating layer side surface, the first blocking trench being recessed from an upper surface of the upper insulating stack in a direction toward the substrate.

### CROSS-REFERENCE TO RELATED APPLICATION

This application is based on and claims priority under 35 U.S.C. § 119 to Korean Patent Application No. 10-2024-0160493, filed on Nov. 12, 2024, in the Korean Intellectual Property Office, the disclosure of which being incorporated by reference herein in its entirety.

### BACKGROUND

The present disclosure relates to a semiconductor chip, and particularly, to a semiconductor chip including one or more blocking trenches and one or more crack propagation prevention structures.

Generally, a wafer on which semiconductor devices are formed is divided into a chip region where a plurality of cells are formed and a scribe lane for separating chips. A plurality of semiconductor devices, such as transistors, resistors, capacitors, and so on are formed in the chip region, and instead of forming the semiconductor devices in the scribe lane, the wafer is sawed along the scribe lane to complete the chips. Cracks may occur at a boundary between the sawed semiconductor chips, and the cracks may propagate to device regions of the semiconductor chips. Due to the cracks propagating to the device regions of the semiconductor chips, defects may occur in the semiconductor chips.

### SUMMARY

It is an aspect to provide a semiconductor chip with improved reliability by preventing cracks from propagating into a device region.

According to an aspect of one or more embodiments, there is provided a semiconductor chip comprising a substrate including a device region and an edge region; a device layer on the substrate, the device layer including a device interlayer insulating layer in the device layer; a wiring layer on the device interlayer insulating layer and including an inner lower insulating stack and an outer lower insulating stack; an upper insulating stack on the wiring layer and including a plurality of upper insulating layers; a first crack propagation prevention structure on the device interlayer insulating layer between a first insulating layer side surface and a second insulating layer side surface, the first insulating layer side surface facing the inner lower insulating stack and the first crack propagation prevention structure and being at least partially included in the upper insulating stack, the second insulating layer side surface facing the outer lower insulating stack and the first crack propagation prevention structure and being at least partially included in the upper insulating stack; and a first blocking trench between the first crack propagation prevention structure and the first insulating layer side surface, the first blocking trench being recessed from an upper surface of the upper insulating stack in a direction toward the substrate.

According to another aspect of one or more embodiments, there is provided a semiconductor chip comprising a substrate including a device region and an edge region; device layer provided on the substrate, the device layer including a device interlayer insulating layer in the device layer; a wiring layer on the device interlayer insulating layer, the wiring layer including an inner lower insulating stack and an outer lower insulating stack; an upper insulating stack on the wiring layer, the upper insulating stack including a plurality of upper insulating layers; a first crack propagation prevention structure between the inner lower insulating stack and the outer lower insulating stack; and a first blocking trench between the first crack propagation prevention structure and the inner lower insulating stack, the first blocking trench being recessed from an upper surface of the upper insulating stack toward the substrate. The first blocking trench surrounds the device region in a planar view, and the first crack propagation prevention structure surrounds the first blocking trench and the device region in a planar view.

According to yet another aspect of one or more embodiments, there is provided a semiconductor chip comprising a substrate including a device region and an edge region; a device layer provided on the substrate, the device layer including a device interlayer insulating layer in the device layer; a wiring layer on the device interlayer insulating layer, the wiring layer including an inner lower insulating stack and an outer lower insulating stack; an upper insulating stack on the wiring layer, the upper insulating stack including a plurality of upper insulating layers; a first crack propagation prevention structure on the device interlayer insulating layer between a first insulating layer side surface and a second insulating layer side surface, the first insulating layer side surface facing the inner lower insulating stack and the first crack propagation prevention structure and being at least partially included in the upper insulating stack, and the second insulating layer side surface facing the outer lower insulating stack and the first crack propagation prevention structure and being at least partially included in the upper insulating stack; a first blocking trench between the first crack propagation prevention structure and the first insulating layer side surface, the first blocking trench being recessed from an upper surface of the upper insulating stack in a direction toward the substrate; a second blocking trench between the first crack propagation prevention structure and the second insulating layer side surface, the second blocking trench being recessed from the upper surface of the upper insulating stack toward the substrate; wiring patterns in the inner lower insulating stack, the wiring patterns including lower line patterns and lower via patterns; a sub pad above the lower via patterns and the lower line patterns; a bonding pad at least partially buried in the upper insulating stack; and upper via patterns electrically connecting the bonding pad to the sub pad. A first depth of the first blocking trench from the upper surface of the upper insulating stack toward the substrate is equal to or greater than a second depth of the second blocking trench from the upper surface of the upper insulating stack toward the substrate. A vertical level of a lowermost portion of the first blocking trench and a vertical level of a lowermost portion of the second blocking trench are lower than a vertical level of an uppermost portion of the first crack propagation prevention structure. The plurality of upper insulating layers include a sixth upper insulating layer between the first insulating layer side surface and the first crack propagation prevention structure, and between the second insulating layer side surface and the first crack propagation prevention structure. The first blocking trench is between the first insulating layer side surface and the first crack propagation prevention structure. The first crack propagation prevention structure includes a plurality of metal layers. The plurality of metal layers correspond to the wiring patterns, the sub pad, the upper via patterns, and the bonding pad, which are respectively located at same vertical levels as the corresponding ones of the plurality of metal layers, and the plurality of metal layers include a same material and have a same thickness as the wiring patterns, the sub pad, the upper via patterns, and the bonding pad, which respectively correspond to the plurality of metal layers.

### BRIEF DESCRIPTION OF THE DRAWINGS

Various embodiments will be more clearly understood from the following detailed description taken in conjunction with the accompanying drawings, in which:

FIG. 1 is a cross-sectional view illustrating a semiconductor package including a semiconductor chip according to an embodiment;

FIG. 2 is a cross-sectional view illustrating a semiconductor chip according to an embodiment;

FIG. 3 is a plan view illustrating a semiconductor chip according to an embodiment;

FIG. 4 is a cross-sectional view illustrating a case in which multiple types of cracks occur in a semiconductor chip according to an embodiment;

FIG. 5 is a cross-sectional view illustrating a semiconductor chip according to an embodiment;

FIG. 6 is a cross-sectional view illustrating a semiconductor chip according to an embodiment;

FIG. 7 is a cross-sectional view illustrating a semiconductor chip according to an embodiment; and

FIG. 8A to FIG. 8K are cross-sectional views sequentially illustrating a process of manufacturing a semiconductor chip, according to an embodiment.

### DETAILED DESCRIPTION

Hereinafter, various embodiments are described in detail with reference to the attached drawings.

Various embodiments are described herein, and following embodiments may be modified into various other forms. The present disclosure is not limited to the following embodiments. A thickness and size of each layer in the drawings are exaggerated for the sake of convenience and clarity of description.

In this specification, the first direction refers to the X direction, the second direction refers to the Y direction, and the first direction may be perpendicular to the second direction. The third direction is the Z direction, and the third direction may be perpendicular to the first direction and the second direction. A horizontal plane or a plane refers to an X-Y plane. An upper surface of a certain object refers to a surface in a positive third direction with respect to the certain object, and a lower surface of a certain object refers to a surface in a negative third direction with respect to the certain object.

In the expressions used herein, the term “top” may refer to the +Z direction based on the direction illustrated in the drawings, and the term “bottom” may refer to the −Z direction opposite to the top. However, this convention is for ease of description, and the terms “top” and “bottom” may refer to a relative arrangement relationship. For example, when components illustrated in a drawing are viewed in the opposite direction, the term “top” used herein may refer to the −Z direction with respect to the direction illustrated in the drawings, and the term “bottom” may refer to the +Z direction.

As used in this specification, a phrase using the form “at least one of A, B, or C” includes within its scope “only A”, “only B”, “only C”, “A and B”, “A and C”, “B and C” and “A, B, and C.”

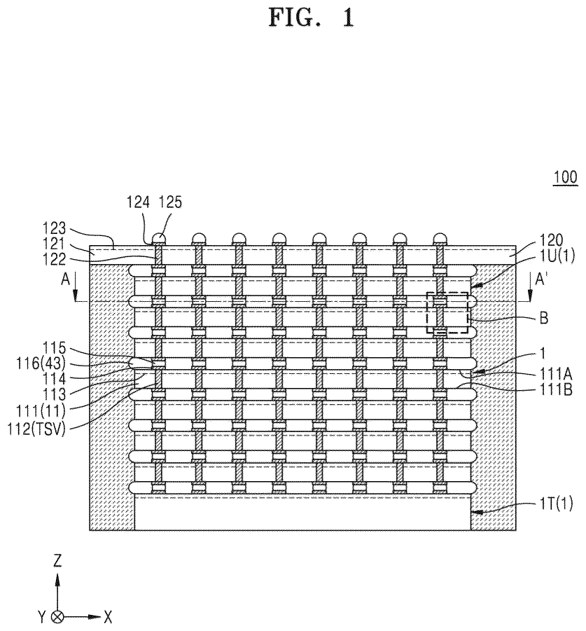

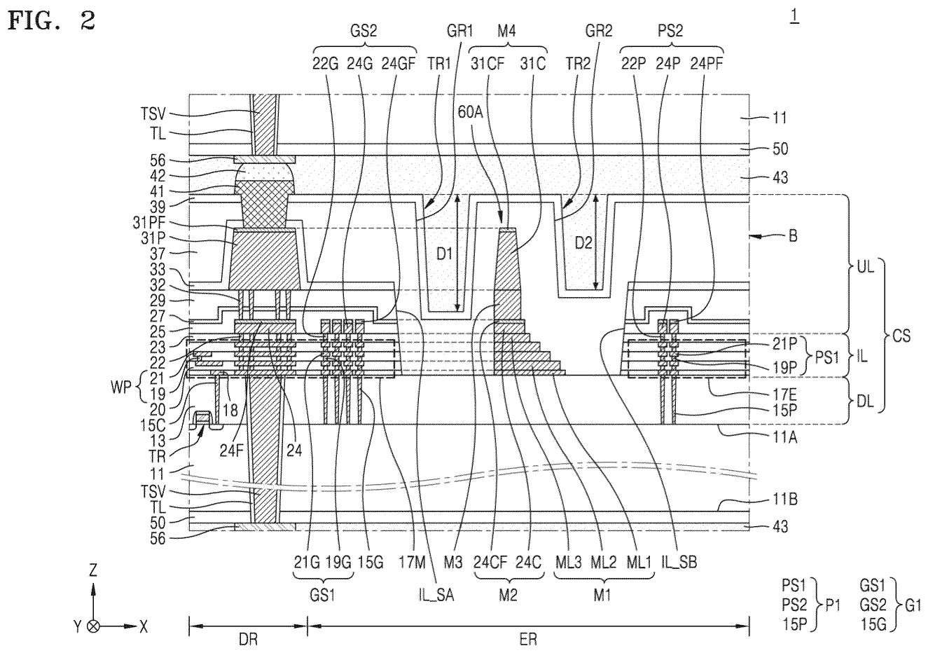

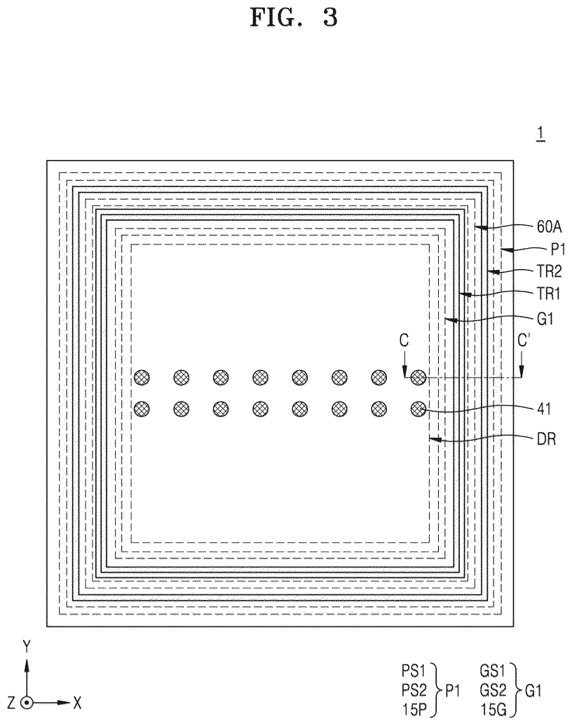

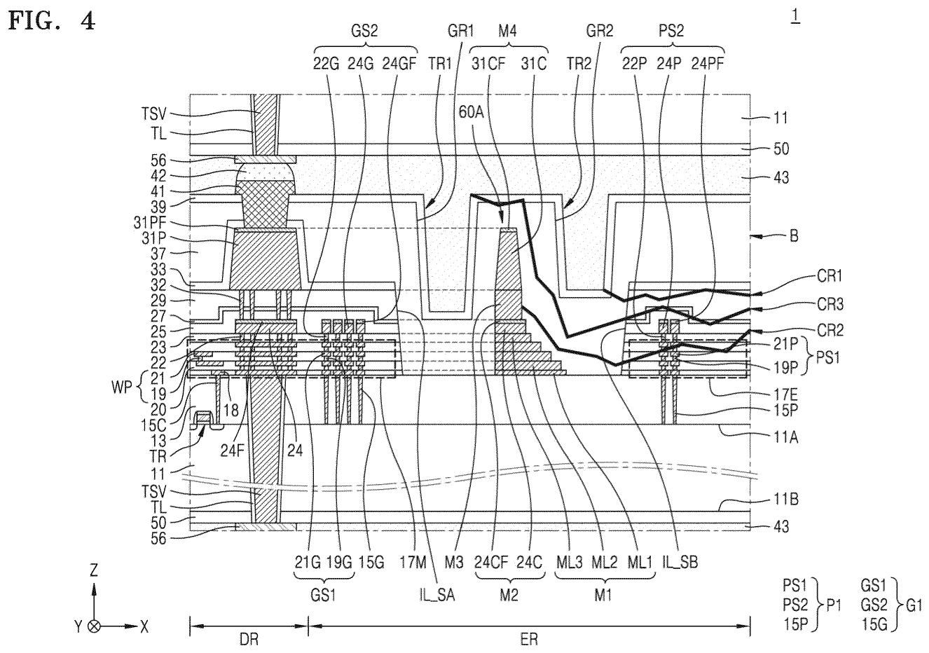

FIG. 1 is a cross-sectional view illustrating a semiconductor package 100 including a semiconductor chip 1 according to an embodiment. FIG. 2 is a cross-sectional view illustrating the semiconductor chip 1 according to an embodiment. FIG. 3 is a plan view illustrating the semiconductor chip 1 according to an embodiment. More specifically, FIG. 2 is an enlarged cross-sectional view illustrating a portion B of FIG. 1 and a portion C-C′ of FIG. 3 corresponding to the portion B of FIG. 1. FIG. 3 is a plan view illustrating a portion A-A′ of FIG. 1. FIG. 4 is a cross-sectional view illustrating a case where multiple types of cracks occur in the semiconductor chip 1 according to an embodiment. In the following description, the semiconductor chip 1 may be referred to as a first semiconductor chip 1.

Referring to FIG. 1, the semiconductor package 100 includes a plurality of first semiconductor chips 1 and a second semiconductor chip 120. Although FIG. 1 illustrates that the semiconductor package 100 includes eight first semiconductor chips 1, the semiconductor package 100 is not limited thereto. For example, the semiconductor package 100 may include two or more first semiconductor chips 1. In some embodiments, the semiconductor package 100 may include a multiple of four first semiconductor chips 1. The plurality of first semiconductor chips 1 may be sequentially stacked on the second semiconductor chip 120. The second semiconductor chip 120 is placed at the top of the semiconductor package 100, and among the plurality of first semiconductor chips 1, the first semiconductor chip 1 that is closest to the second semiconductor chip 120 may be referred to as an uppermost semiconductor chip 1U of the semiconductor package 100, and the first semiconductor chip 1 that is farthest from the second semiconductor chip 120 may be referred to as a lowermost semiconductor chip 1T of the semiconductor package 100.

In some embodiments, among the plurality of first semiconductor chips 1, a vertical thickness of the lowermost first semiconductor chip 1T may be substantially equal to vertical thicknesses of the other first semiconductor chips 1, or the vertical thickness of the lowermost first semiconductor chip 1 may be greater than the vertical thickness of the other first semiconductor chips 1.

The plurality of first semiconductor chips 1 and the second semiconductor chip 120 included in the semiconductor package 100 may be electrically connected to each other through first chip pads 114, second chip pads 124, and chip connection terminals 115, and may transmit and receive signals and provide power and ground. The plurality of first semiconductor chips 1 may be electrically connected to each other through the adjacent first chip pads 114 and the chip connection terminals 115 provided therebetween.

The plurality of first semiconductor chips 1 may each include a first substrate 11 having an active surface and an inactive surface opposite to each other, a first active surface 113 on which a first semiconductor device is formed on a part of the first substrate 11, a wiring structure formed on the first active surface 113 of the first substrate 11, and a plurality of first through-electrodes 112 connected to the wiring structure and passing through at least part of the first semiconductor chip 1. Among the plurality of first semiconductor chips 1, the lowermost first semiconductor chip 1T may omit the plurality of first through-electrodes 112.

The second semiconductor chip 120 may include a second semiconductor substrate 121 having an active surface and an inactive surface opposite to each other, a second active surface 123 on which a second semiconductor device is formed on a part of the second semiconductor substrate 121, and a second wiring structure formed on the second active surface 123 of the second semiconductor substrate 121. The second semiconductor chip 120 may further include a plurality of second through-electrodes 122 connected to the second wiring structure and passing through at least part of the second semiconductor chip 120. The plurality of first through-electrodes 112 and the plurality of second through-electrodes 122 may each be formed as a through silicon via (TSV) and may be referred to as a TSV.

In some embodiments, a first semiconductor substrate 111 and the second semiconductor substrate 121 may each include a semiconductor material, such as silicon (Si). In some embodiments, the first semiconductor substrate 111 and the second semiconductor substrate 121 may each include a semiconductor material, such as germanium (Ge). The first semiconductor substrate 111 and the second semiconductor substrate 121 may each have an active surface and an inactive surface opposite to the active surface. The first semiconductor substrate 111 and the second semiconductor substrate 121 may each include a conductive region, for example, a well doped with an impurity. The first semiconductor substrate 111 and the second semiconductor substrate 121 may each have various device isolation structures, such as a shallow trench isolation (STI) structure.

Semiconductor devices respectively formed on the first semiconductor substrate 111 and the second semiconductor substrate 121 may include a plurality of individual devices of various types. The plurality of individual devices may include various microelectronic devices, for example, metal oxide semiconductor field effect transistors (MOSFETs) such as complementary metal oxide semiconductor (CMOS) transistors, system LSIs (large scale integrations), image sensors such as CMOS imaging sensors (CISs), micro-electro-mechanical system (MEMS), active devices, and/or passive devices, etc.

The plurality of individual devices may be electrically connected to the conductive region of the first semiconductor substrate 111 or the second semiconductor substrate 121. The first semiconductor device and the second semiconductor device may each further include conductive wires or conductive plugs that electrically connecting at least two of the plurality of individual devices to each other, or the plurality of individual devices to the conductive region of each of the first semiconductor substrate 111 and the second semiconductor substrate 121. The plurality of individual devices may be electrically separated from other adjacent individual devices by an insulating layer.

The plurality of first semiconductor chips 1 may be memory semiconductor chips. In some embodiments, the second semiconductor chip 120 may be a buffer chip that includes a serial-parallel conversion circuit and controls the plurality of first semiconductor chips 1, and the plurality of first semiconductor chips 1 may be respectively memory chips including memory cells. For example, the semiconductor package 100 including the plurality of first semiconductor chips 1 and the second semiconductor chip 120 may be a high bandwidth memory (HBM), and the plurality of first semiconductor chips 1 may each be referred to as a DRAM die, and the second semiconductor chip 120 may be referred to as an HBM control die.

In some embodiments, a horizontal width of the second semiconductor chip 120 may be greater than horizontal widths of the plurality of first semiconductor chips 1. In some embodiments, a vertical height of the second semiconductor chip 120 may be substantially equal to vertical heights of the plurality of first semiconductor chips 1. For example, in some embodiments, the vertical height of each of the plurality of first semiconductor chips 1 and the vertical height of the second semiconductor chip 120 may be about 50 mm to about 90 mm.

An inter-chip molding material 116 may be provided between the plurality of first semiconductor chips 1 and between the uppermost first semiconductor chip 1U and the second semiconductor chip 120. The inter-chip molding material 116 may include a non-conductive film (NCF) or a non-conductive paste (NCP).

The plurality of second connection pads 124 may be provided on one surface of the second semiconductor chip 120. The plurality of second connection pads 124 may be respectively and electrically connected to the plurality of second through-electrodes 122. A plurality of second connection terminals 125 may each be provided on one surface of each of the plurality of second connection pads 124.

In some embodiments, two adjacent chips among the plurality of first semiconductor chips 1 may be electrically connected to each other through direct bonding, and the uppermost semiconductor chip 1U may be electrically connected to the second semiconductor chip 120 through direct bonding, unlike the electrical connection between the plurality of first semiconductor chips 1 and between the uppermost semiconductor chip 1U and the second semiconductor chip 120 through the chip connection terminal 115 as illustrated in FIG. 1.

The direct bonding of two chips may include direct bonding of conductive components of the two chips facing each other and direct bonding of insulating components of the two chips facing each other. Direct bonding of insulating components may include chemical bonding of the insulating components. Direct bonding of two chips may include hybrid bonding. During a direct bonding process, metal atoms included in the bonding pads between adjacent semiconductor chips may diffuse to form an integrated bonding pad.

Referring to FIG. 2 and FIG. 3, in an embodiment, the first semiconductor chip 1 may include the first substrate 11 and a circuit structure CS. The first substrate 11 may include, for example, a semiconductor material. The first substrate 11 may be a silicon single crystal substrate. The first substrate 11 may include a device region DR and an edge region ER surrounding the device region. The first substrate 11 may have a first surface 11A and a second surface 11B opposite to the first surface 11A. The circuit structure CS may be arranged on the first surface 11A of the first substrate 11. The circuit structure CS may include a device layer DL, a wiring layer IL, and an upper insulating stack UL that are sequentially stacked.

Transistors TR may be arranged on the first surface 11A in the device region DR of the first substrate 11. A device separation pattern, memory cells, capacitors, and so on may be provided in the device region DR on the first surface 11A. The first surface 11A of the first substrate 11 may be covered with a device interlayer insulating layer 13. The device interlayer insulating layer 13 may have a single-layer structure or multi-layer structure including one or more of, for example, silicon oxide, silicon nitride, and silicon oxynitride.

Contact plugs 15C respectively connected to the transistors TR may be arranged in the device interlayer insulating layer 13 in the device region DR. First guide ring patterns 15G and first chipping dams 15P may be provided in the device interlayer insulating layer 13 in the edge region ER.

The contact plugs 15C, the first guide ring patterns 15G, and the first chipping dams 15P may include the same material, for example, tungsten. Side surfaces and bottom surfaces of the contact plugs 15C, the first guide ring patterns 15G, and the first chipping dams 15P may be covered with a barrier metal. The barrier metal may include, for example, at least one of titanium, titanium nitride, tantalum, tantalum nitride, or tungsten nitride. The contact plugs 15C, the first guide ring patterns 15G, and the first chipping dams 15P may each pass through at least part of the device interlayer insulating layer 13. The device layer DL may include the transistors TR, the device interlayer insulating layer 13, the contact plugs 15C, the first guide ring patterns 15G, and the first chipping dams 15P.

In a planar view, the first guide ring patterns 15G may have a ring shape surrounding the device region DR. The first guide ring patterns 15G may protect the device layer DL in the device region DR from moisture or physical cracks. As illustrated in FIG. 3, in a planar view, the first chipping dams 15P may have a ring shape and may surround the first guide ring patterns 15G at the same time as having a ring shape surrounding the device region DR. As illustrated in FIG. 3, in a planar view, the first chipping dams 15P may surround a first blocking trench TR1, a first crack propagation prevention structure 60A, and a second blocking trench TR2, which will be described below. The first chipping dams 15P may protect the device layer DL in the device region DR from moisture or physical cracks.

The wiring layer IL may be provided on the device interlayer insulating layer 13. The wiring layer IL may include an inner lower insulating stack 17M, an outer lower insulating stack 17E, lower line patterns 21, lower via patterns 19, a lower guide ring structure GS1, and a lower chipping dam structure PS1. The inner lower insulating stack 17M may be separated from the outer lower insulating stack 17E. The lower via patterns 19 formed integrally with the lower line patterns 21 may be referred to as wiring patterns WP.

The inner lower insulating stack 17M and the outer lower insulating stack 17E may each include lower inter-metallic dielectric layers 20 which are multiple layers. The lower inter-metallic dielectric layers 20 may each have a low-k material having a dielectric constant lower than a dielectric constant of silicon oxide. For example, the lower inter-metallic dielectric layers 20 may be porous dielectric layers. The lower inter-metallic dielectric layers 20 may each include SiOCH. A mechanical strength of each of the lower inter-metallic dielectric layers 20 may be lower than a mechanical strength of the device interlayer insulating layer 13. An etch-stop layer may be provided between the lower intermetal insulating layers 20. The etch-stop layer may include one of, for example, silicon nitride, silicon oxynitride, and silicon carbon nitride.

The inner lower insulating stack 17M may cover the device region DR and a part of the edge region ER adjacent to the device region DR. The outer lower insulating stack 17E may have a ring shape in a planar view, be arranged in the edge region ER, and surround the inner lower insulating stack 17M. A sidewall of the outer lower insulating stack 17E may be exposed. The inner lower insulating stack 17M may be separated from the outer lower insulating stack 17E and be provided on the same vertical level as the outer lower insulating stack 17E. The first blocking trench TR1, the first crack propagation prevention structure 60A, and the second blocking trench TR2 may be provided between the inner lower insulating stack 17M and the outer lower insulating stack 17E which are separated from each other.

In the device region DR, the wiring layer IL may include the lower line patterns 21 arranged in the inner lower insulating stack 17M and the lower via patterns 19 which are arranged in the inner lower insulating stack 17M and connect the lower line patterns 21. Among the lower line patterns 21 provided on the device interlayer insulating layer 13, the lower line patterns 21 arranged at the lowermost layer may be referred to as the lowermost lower line patterns 18. In the edge region ER, the wiring layer IL may include the lower guide ring structure GS1 in the inner lower insulating stack 17M. In the edge region ER, the wiring layer IL may include the lower chipping dam structure PS1 in the outer lower insulating stack 17E. In some embodiments, the lower chipping dam structure PS1 may be arranged in the inner lower insulating stack 17M in the edge region ER, unlike the illustration in FIG. 2.

The lower guide ring structure GS1 may include second guide ring patterns 21G, and third guide ring patterns 19G connecting the second guide ring patterns 21G. The second guide ring patterns 21G may be at the same vertical level as the lower line patterns 21 and may include the same material as the lower line patterns 21. The third guide ring patterns 19G may be at the same height as the lower via patterns 19 and may include the same material as the lower via patterns 19.

In a planar view, both the second guide ring patterns 21G and the third guide ring patterns 19G may have a ring shape surrounding the device region DR. The lower guide ring structure GS1 may protect the wiring layer IL in the device region DR from moisture or physical cracks.

The wiring layer IL may include the lower chipping dam structure PS1 in the outer lower insulating stack 17E. The lower chipping dam structure PS1 may include second chipping dam patterns 21P and third chipping dam patterns 19P connecting the second chipping dam patterns 21P. The second chipping dam patterns 21P may be at the same height as the lower line patterns 21 and may include the same material as the lower line patterns 21. The third chipping dam patterns 19P may be at the same height as the lower via patterns 19 and may include the same material as the lower via patterns 19. In a planar view, both the second chipping dam patterns 21P and the third chipping dam patterns 19P may have a ring shape surrounding the lower guide ring structure GS1. In a planar view, both the second chipping dam patterns 21P and the third chipping dam patterns 19P may have a ring shape surrounding the first crack propagation prevention structure 60A. The lower chipping dam structure PS1 may additionally protect the wiring layer IL in the device region DR from moisture or physical cracks.

The upper insulating stack UL may be arranged on the wiring layer IL. The upper insulating stack UL may include a first upper intermetal insulating layer 23, a second upper intermetal insulating layer 25, a third upper intermetal insulating layer 27, a fourth upper intermetal insulating layer 29, a fifth upper intermetal insulating layer 33, and a sixth upper intermetal insulating layer 37 that are sequentially stacked. The first, second, third, fourth, fifth, and sixth upper intermetal insulating layers 23, 25, 27, 29, 33, and 37 may each include an insulating material having a higher dielectric constant than dielectric constants of the lower intermetal insulating layers 20. Mechanical strengths of the first, second, third, fourth, fifth, and sixth upper intermetal insulating layers 23, 25, 27, 29, 33, and 37 may be greater than mechanical strengths of the lower intermetal insulating layers 20.

A sub pad 24, fifth guide ring patterns 24G, and fifth chipping dam patterns 24P may be provided on the first upper intermetal insulating layer 23. A sub pad metal layer 24F may be provided on each of the sub pad 24, a fifth guide ring pattern metal layer 24GF may be provided on each of the fifth guide ring patterns 24G, and a fifth chipping dam pattern metal layer 24PF may be provided on each of the fifth chipping dam patterns 24P.

The sub pad 24 may be arranged in the device region DR, and the fifth guide ring patterns 24G and the fifth chipping dam patterns 24P may be arranged in the edge region ER. The sub pad 24, the fifth guide ring patterns 24G, and the fifth chipping dam patterns 24P may be at the same vertical level, may be formed of the same material, and may also have the same thickness. The sub pad 24 may be provided on the first upper intermetal insulating layer 23. The sub pad metal layer 24F may cover an upper surface of the sub pad 24.

First upper via patterns 22 may pass through the first upper intermetal insulating layer 23 and may each connect one of the lower line patterns 21 to the sub pad 24. The fourth guide ring patterns 22G may pass through the first upper intermetal insulating layer 23 and may respectively connect the second guide ring patterns 21G to the fifth guide ring patterns 24G. The fourth chipping dam patterns 22P may pass through the first upper intermetal insulating layer 23 and may respectively connect the second chipping dam patterns 21P to the fifth chipping dam patterns 24P.

The first upper via patterns 22, the fourth guide ring patterns 22G, and the fourth chipping dam patterns 22P may be at the same vertical level, may be formed of the same material, and may have the same thickness.

An upper guide ring structure GS2 may include the fourth guide ring patterns 22G, the fifth guide ring patterns 24G, and the fifth guide ring pattern metal layer 24GF. The fifth guide ring patterns 24G may be provided on the first upper intermetal insulating layer 23, the fifth guide ring patterns 24G may be respectively connected to the second guide ring patterns 21G respectively by the fourth guide ring patterns 22G passing through the first upper intermetal insulating layer 23. Upper surfaces of the fourth guide ring patterns 22G may be covered by the fifth guide ring pattern metal layer 24GF.

In a planar view, the upper guide ring structure GS2 may surround the device region DR. The fourth chipping dam patterns 22P and the fifth chipping dam patterns 24P may be included in an upper chipping dam structure PS2. In a planar view, the upper chipping dam structure PS2 may surround the upper guide ring structure GS2. The upper guide ring structure GS2 and the upper chipping dam structure PS2 may protect the device region DR from moisture or physical cracks.

The second, third, and fourth upper intermetal insulating layers 25, 27, and 29 may be sequentially stacked on the first upper intermetal insulating layer 23, the sub pad 24, the fifth guide ring patterns 24G, and the fifth chipping dam patterns 24P. The first upper intermetal insulating layer 23 and the second upper intermetal insulating layer 25 may each include, for example, silicon oxide, tetraethyl orthosilicate (TEOS), or high density plasma (HDP) oxide.

The second upper intermetal insulating layer 25 may function as an etch-stop layer. The third upper intermetal insulating layer 27 may include, for example, silicon nitride. In some embodiments, the third upper intermetal insulating layer 27 may include a material having low hydrogen permeability. The third upper intermetal insulating layer 27 may function as a hydrogen blocking layer. For example, the third upper intermetal insulating layer 27 may include at least one of aluminum oxide (AlOₓ), tungsten oxide (WOₓ), or silicon nitride (SiNₓ).

The fourth, fifth, and sixth upper intermetal insulating layers 29, 33, and 37 may each include one of HDP oxide, undoped silicate glass (USG), TEOS, SiN, SiO₂, SiOC, SiON, or SiCN.

Second upper via patterns 32 may pass through the second to fourth upper intermetal insulating layers 25, 27, and 29 and be in contact with the sub pad 24. A bonding pad 31P may be arranged on the fourth upper intermetal insulating layer 29 in the device region DR. A lower surface of the bonding pad 31P may be connected to the second upper via patterns 32 passing through the fourth upper intermetal insulating layer 29. A bonding pad metal layer 31PF may be provided on an upper surface of the bonding pad 31P. A part of the bonding pad 31P may be buried in the sixth upper intermetal insulating layer 37, the fifth upper intermetal insulating layer 33, and the upper passivation layer 39.

The fifth upper intermetal insulating layer 33 may extend on the fourth upper intermetal insulating layer 29 and a surface of the bonding pad 31P to be substantially conformally provided on the fourth upper intermetal insulating layer 29 and the bonding pad 31P.

The sixth upper intermetal insulating layer 37 may extend on the fifth upper intermetal insulating layer 33 and the device interlayer insulating layer 13 to be provided on the fifth upper intermetal insulating layer 33 and the device interlayer insulating layer 13. The sixth upper intermetal insulating layer 37 may include a first blocking groove GR1 formed as a groove in which a part of the sixth upper intermetal insulating layer 37 is recessed and which is directed toward the first substrate 11. The sixth upper intermetal insulating layer 37 may include a second blocking groove GR2 formed as a groove in which a part of the sixth upper intermetal insulating layer 37 is recessed and which is directed toward the first substrate 11.

The first blocking groove GR1 may be provided between the first crack propagation prevention structure 60A and the inner lower insulating stack 17M. The sixth upper intermetal insulating layer 37 may be provided between the inner lower insulating stack 17M, the first, second, third, fourth, and fifth upper intermetal insulating layers 23, 25, 27, 29, and 33 on the inner lower insulating stack 17M, and the first crack propagation prevention structure 60A. The first, second, third, fourth, and fifth upper intermetal insulating layers 23, 25, 27, 29, and 33 and the lower intermetal insulating layers 20 may face the first crack propagation prevention structure 60A and be in contact with the sixth upper intermetal insulating layer 37, and one surface adjacent to the inner lower insulating stack 17M may be referred to as a first insulating layer side surface IL_SA.

The first blocking groove GR1 may be provided between the first insulating layer side surface IL_SA and the first crack propagation prevention structure 60A. The first blocking groove GR1 having a recessed groove shape in a direction of the interlayer insulating layer 13 from one surface of the sixth upper intermetal insulating layer 37 may be provided in the sixth upper intermetal insulating layer 37 between the first crack propagation prevention structure 60A and the inner lower insulating stack 17M.

The second blocking groove GR2 may be provided between the first crack propagation prevention structure 60A and the outer lower insulating stack 17E. The sixth upper intermetal insulating layer 37 may be provided between the outer lower insulating stack 17E, the first, second, third, fourth, and fifth upper intermetal insulating layers 23, 25, 27, 29, and 33 provided on the outer lower insulating stack 17E, and the first crack propagation prevention structure 60A.

The first, second, third, fourth, and fifth upper intermetal insulating layers 23, 25, 27, 29, and 33 and the lower intermetal insulating layers 20 may face the first crack propagation prevention structure 60A and be in contact with the sixth upper intermetal insulating layer 37, and a surface adjacent to the outer lower insulating stack 17E may be referred to as a second insulating layer side surface IL_SB.

The first blocking groove GR1 may be provided between the second insulating layer side surface IL_SB and the first crack propagation prevention structure 60A. The second blocking groove GR2 having a recessed groove shape in a direction of the interlayer insulating layer 13 from one surface of the sixth upper intermetal insulating layer 37 may be provided in the sixth upper intermetal insulating layer 37 between the first crack propagation prevention structure 60A and the outer lower insulating stack 17M.

The upper passivation layer 39 may be provided on an upper insulating stack UL. The upper passivation layer 39 may extend along a surface of the sixth upper intermetal insulating layer 37. That is, the upper passivation layer 39 may be substantially conformally provided along surfaces of the first blocking groove GR1 and the second blocking groove GR2 formed on the sixth upper intermetal insulating layer 37. The upper passivation layer 39 may have a single-layer structure or multi-layer structure including one or more of silicon oxide, silicon nitride, and/or SiCN.

A groove formed by substantially uniformly providing the upper passivation layer 39 in the first blocking groove GR1 may be referred to as the first blocking trench TR1. The first blocking trench TR1 may be a groove recessed from an upper surface of the upper passivation layer 39 toward the first substrate 11. Likewise, a groove formed by substantially uniformly providing the upper passivation layer 39 in the second blocking groove GR2 may be referred to as the second blocking trench TR2. The second blocking trench TR2 may be a groove recessed from the upper surface of the upper passivation layer 39 toward the first substrate 11. A distance from the upper surface of the upper passivation layer 39 to the deepest surface of the groove of the first blocking trench TR1 may be referred to as a first depth D1 as illustrated in FIG. 2, and a distance from the upper surface of the upper passivation layer 39 to the deepest surface of the groove of the second blocking trench TR2 may be referred to as the second depth D2 as illustrated in FIG. 2.

The first depth D1 of the first blocking trench TR1 may be less than a vertical level from the device interlayer insulating layer 13 to the upper surface of the upper passivation layer 39. The second depth D2 of the second blocking trench TR2 may be less than the vertical level from the device interlayer insulating layer 13 to the upper surface of the upper passivation layer 39. The first depth D1 of the first blocking trench TR1 may be equal to or greater than the second depth D2 of the second blocking trench TR2. Because the first depth D1 of the first blocking trench TR1 is greater than the second depth D2 of the second blocking trench TR2, the first blocking trench TR1 may effectively block a crack transferred through the second blocking trench TR2 and the first crack propagation prevention structure 60A.

The first blocking trench TR1 and the second blocking trench TR2 may each have a tapered shape in which a horizontal width of the first blocking trench TR1 and a horizontal width of the second blocking trench TR2 are reduced toward the device interlayer insulating layer 13 or the first substrate 11.

A conductive bump 41 may pass through the upper passivation layer 39 and the fifth and sixth upper intermetal insulating layers 33 and 37 to be in contact with the bonding pad 31P. The conductive bump 41 may be arranged in a hole formed in the fifth and sixth upper intermetal insulating layers 33 and 37. A side surface of the conductive bump 41 may be in contact with the upper passivation layer 39 and the fifth and sixth upper intermetal insulating layers 33 and 37. A part of the conductive bump 41 may protrude above the upper passivation layer 39.

A connection terminal 42 may be provided on the conductive bump 41. The connection terminal 42 may be, for example, a solder ball, and the connection terminal 42 may include at least one of tin (Sn), silver (Ag), copper (Cu), lead (Pb), or aluminum (Al).

The bonding pad 31P may include a metal, and the bonding pad 31P may include at least one of, for example, copper (Cu), nickel (Ni), palladium (Pd), silver (Ag), chromium (Cr), titanium (Ti), tin (Sn), silver (Ag), gold (Au), or an alloy thereof.

The conductive bump 41 may include a metal, and include at least one of, for example, copper (Cu), nickel (Ni), palladium (Pd), silver (Ag), chromium (Cr), titanium (Ti), tin (Sn), silver (Ag), gold (Au), or an alloy thereof.

The second surface 11B of the first substrate 11 may be covered with a lower passivation layer 50. The lower passivation layer 50 may have a single-layer structure or multi-layer structure including one or more of, for example, silicon oxide, silicon nitride, and SiCN.

In the device region DR, a through-hole electrode TSV may pass through the device interlayer insulating layer 13, the first substrate 11, and the lower passivation layer 50. The through-hole electrode TSV may be in contact with at least one of the lower line patterns 21. A through-hole insulating layer TL may be provided between the through-hole electrode TSV and the first substrate 11. The through-hole insulating layer TL may be, for example, silicon oxide. A lower bonding pad 56 may be under the lower passivation layer 50, and at least part of one surface of the lower bonding pad 56 may be in contact with one end surface of the through-hole electrode TSV exposed from the lower passivation layer 50. The through-hole electrode TSV may include at least one of, for example, copper (Cu), aluminum (Al), silver (Ag), tin (Sn), gold (Au), nickel (Ni), lead (Pb), titanium (Ti), tungsten (W), or an alloy thereof.

The lower bonding pad 56 may include a metal or may include at least one of, for example, copper (Cu), nickel (Ni), palladium (Pd), silver (Ag), chromium (Cr), titanium (Ti), tin (Sn), silver (Ag), and gold (Au), and an alloy thereof.

The first semiconductor chip 1 may be electrically connected to an adjacent semiconductor chip. For example, an inter-chip molding material 43 may be provided between the first semiconductor chip 1 and the adjacent semiconductor chip. The inter-chip molding material 43 of FIG. 2 may correspond to the inter-chip molding material 116 of FIG. 1. The inter-chip molding material 43 may include a non-conductive film (NCF) or a non-conductive paste (NCP). The inter-chip molding material 43 may be filled inside the first blocking trench TR1 and the second blocking trench TR2.

A first guide ring G1 may include the lower guide ring structure GS1, the upper guide ring structure GS2, and the first guide ring patterns 15G. The first guide ring G1 may be provided on the device interlayer insulating layer 13 laterally separated from the sub pad 24 or the through-hole electrode TSV. In some embodiments, a first guide ring G2 may be provided on the device interlayer insulating layer 13 laterally separated from the device region DR.

A first chipping dam P1 may include the lower chipping dam structure PS1, the upper chipping dam structure PS2, and the first chipping dams 15P. The lower chipping dam structure PS1 may be provided on the device interlayer insulating layer 13 laterally separated from the sub pad 24 or the through-hole electrode TSV. The first chipping dam P1 may be separated from the first guide ring G1. For example, a part of the first chipping dam P1 may be provided on the outer lower insulating stack 17E. In some embodiments, a part of the first chipping dam P1 may also be provided in the inner lower insulating stack 17M.

As illustrated in FIG. 2, the first guide ring G1 may be provided in the inner lower insulating stack 17M, and the first chipping dam P1 may be provided in the outer lower insulating stack 17E. In some embodiments, in some embodiments, both the first guide ring G1 and the first chipping dam P1 may be provided in the inner lower insulating stack 17M. In some embodiments, both the first guide ring G1 and the first chipping dam P1 may be provided in the outer lower insulating stack 17E.

As illustrated in FIG. 2 and FIG. 3, both the first guide ring G1 and the first chipping dam P1 may be provided in the semiconductor chip 1. In some embodiments, a plurality of guide rings or/and a plurality of chipping dam structures may be included in the semiconductor chip 1.

As illustrated in FIG. 3, in a planar view, the first guide ring G1 may be provided outside the device region DR to surround the device region DR. The first blocking trench TR1, the first crack propagation prevention structure 60A, and the second blocking trench TR2 may sequentially surround the device region DR. That is, in a planar view, the first blocking trench TR1 may be provided outside the first guide ring G1 to surround the first guide ring G1, and the first crack propagation prevention structure 60A may be provided outside the first blocking trench TR1 to surround the first blocking trench TR1. The second blocking trench TR2 may be provided outside the first crack propagation prevention structure 60A to surround the first crack propagation prevention structure 60A, and the first chipping dam P1 may be provided outside the second blocking trench TR2 to surround the second blocking trench TR2. That is, the device region DR may be sequentially surrounded by the first guide ring G1, the first blocking trench TR1, the first crack propagation prevention structure 60A, the second blocking trench TR2, and the first chipping dam P1.

The order of surrounding may be changed depending on the number of blocking trenches and the number of crack propagation prevention structures, and may be changed depending on the number of guide rings and the number of chipping dam structures at the time of designing the semiconductor chip 1. The arrangement of guide rings and the arrangement of chipping dam structures may be changed according to the design of the semiconductor chip 1.

The first crack propagation prevention structure 60A may be provided between the inner lower insulating stack 17M and the outer lower insulating stack 17E. The first crack propagation prevention structure 60A may be provided on the device interlayer insulating layer 13 and be surrounded by the sixth upper intermetal insulating layer 37. The first crack propagation prevention structure 60A may be provided between the second blocking trench TR2 and the outer lower insulating stack 17E described above. The first crack propagation prevention structure 60A may be provided between the first blocking trench TR1 and the inner lower insulating stack 17M. The first crack propagation prevention structure 60A may be provided between the first blocking trench TR1 and the second blocking trench TR2.

The first crack propagation prevention structure 60A may face the first insulating layer side surface IL_SA, and the sixth upper intermetal insulating layer 37 may be provided between the first crack propagation prevention structure 60A and the first insulating layer side surface IL_SA. The first crack propagation prevention structure 60A may face the second insulating layer side surface IL_SB, and the sixth upper intermetal insulating layer 37 may be provided between the first crack propagation prevention structure 60A and the second insulating layer side surface IL_SB.

The sixth upper intermetal insulating layer 37 may be between the first crack propagation prevention structure 60A and the first insulating layer side surface IL_SA to be in direct contact with the device interlayer insulating layer 13, and may be between the first crack propagation prevention structure 60A and the second insulating layer side surface IL_SB to be in direct contact with the device interlayer insulating layer 13.

The first crack propagation prevention structure 60A may include a first metal structure M1, a second metal structure M2, a third metal structure M3, and a fourth metal structure M4. The first metal structure M1 may include a plurality of stacked metal layers. For example, the first metal structure M1 may include a first metal layer ML1, a second metal layer ML2, and a third metal layer ML3.

The first metal structure M1, the second metal structure M2, the third metal structure M3, and the fourth metal structure M4 included in the first crack propagation prevention structure 60A may be formed together with other configurations of the semiconductor chip 1. That is, other configurations than the first crack propagation prevention structure 60A of the semiconductor chip 1 may be formed in the same manufacturing process as the first metal structure M1, the second metal structure M2, the third metal structure M3, and the fourth metal structure M4. Detailed descriptions thereof are made below.

The first metal structure M1 may include a plurality of metal layers. For example, the first metal structure M1 may include the first metal layer ML1, the second metal layer ML2, and the third metal layer ML3. That is, the first metal layer ML1, the second metal layer ML2, and the third metal layer ML3 may be included in the plurality of metal layers.

The plurality of metal layers included in the first metal structure M1 may be sequentially stacked. As illustrated in FIG. 2, the plurality of metal layers included in the first metal structure M1 may be sequentially stacked with horizontal widths decreasing in a direction away from the first substrate 11 or the device interlayer insulating layer 13. For example, the first metal layer ML1 may be arranged on the device interlayer insulating layer 13, and at least one second metal layer ML2 may be arranged on the first metal layer ML1. The third metal layer ML3 may be arranged on the second metal layer ML2.

For example, a configuration corresponding to the first metal layer ML1 may include the lowermost lower line patterns 18 provided directly on the device interlayer insulating layer 13. A configuration corresponding to the second metal layer ML2 may include the lower line patterns 21 and the lower via patterns 19 formed integrally with the lower line patterns 21. That is, the configuration corresponding to the second metal layer ML2 may include the wiring patterns WP. A configuration corresponding to the third metal layer ML3 may include the first upper via patterns 22. The first metal layer ML1 may be formed in the same process as the lower line patterns 21 formed directly above the device interlayer insulating layer 13, the second metal layer ML2 may be formed in the same process as the wiring patterns WP, and the third metal layer ML3 may be formed in the same process as the first upper via patterns 22.

The lowermost lower line patterns 18 provided directly above the device interlayer insulating layer 13, the second guide ring patterns 21G provided directly above the device interlayer insulating layer 13, and the second chipping dam patterns 21P provided directly above the device interlayer insulating layer 13 may be at the same vertical level as the first metal layer ML1 of the first metal structure M1. That is, the lowermost lower line patterns 18 provided directly above the device interlayer insulating layer 13 corresponding to the first metal layer ML1 of the first metal structure M1, the second guide ring patterns 21G provided directly above the device interlayer insulating layer 13, and the second chipping dam patterns 21P provided directly above the device interlayer insulating layer 13 may be at the same vertical level.

The first metal layer ML1 of the first metal structure M1, the lowermost lower line patterns 18 provided directly above the device interlayer insulating layer 13, the second guide patterns 21G provided directly above the device interlayer insulating layer 13, and the second chipping dam patterns 21P provided directly above the device interlayer insulating layer 13 may be formed of the same material and may also have the same thickness, because the lowermost lower line patterns 18, the second guide ring patterns 21G, and the second chipping dam patterns 21P provided directly above the device interlayer insulating layer 13 are all formed in the same process as the first metal layer ML1 of the first metal structure M1.

The wiring patterns WP, the second guide ring patterns 21G, the third guide ring patterns 19G provided integrally with the second guide ring patterns 21G, the second chipping dam patterns 21P, and the third chipping dam patterns 19P provided integrally with the second chipping dam patterns 21P may be at the same vertical level as the second metal layer ML2 of the first metal structure M1. That is, the wiring patterns WP corresponding to the second metal layer ML2 of the first metal structure M1, the second guide ring patterns 21G, the third guide ring patterns 19G provided integrally with the second guide ring patterns 21G, the second chipping dam patterns 21P, and the third chipping dam patterns 19P provided integrally with the second chipping dam patterns 21P may be formed of the same material and may also have the same thickness because the wiring patterns WP, the second guide ring patterns 21G, the third guide ring patterns 19G provided integrally with the second guide ring patterns 21G, the second chipping dam patterns 21P, and the third chipping dam patterns 19P provided integrally with the second chipping dam patterns 21P are all formed of metals in the same process as the second metal layer ML2 of the first metal structure M1.

The wiring patterns WP may be formed integrally with each other during a manufacturing process. For example, the lower line patterns 21 and the lower via patterns 19 formed integrally with the lower line patterns 21 may be formed through a single deposition process. Likewise, the second guide ring patterns 21G and the third guide ring patterns 19G formed integrally with the second guide ring patterns 21G may be formed through a single deposition process, and the second chipping dam patterns 21P and the third chipping dam patterns 19P formed integrally with the second chipping dam patterns 21P may be formed through a single deposition process.

The first upper via patterns 22, the fourth guide ring patterns 22G provided directly below the fifth guide ring patterns 24G, and the fourth chipping dam patterns 22P provided directly below the fifth chipping dam patterns 24P may be at the same vertical level as the third metal layer ML3 of the first metal structure M1, may be formed of the same material, and may also have the same thickness, because the first upper via patterns 22, the fourth guide ring patterns 22G provided directly below the fifth guide ring patterns 24G, and the fourth chipping dam patterns 22P provided directly below the fifth chipping dam patterns 24P are all formed of metals in the same process as the first metal layer ML1 of the first metal structure M1.

The second metal structure M2 may include a fourth metal layer 24C and a fifth metal layer 24CF. Likewise, the fourth metal layer 24C and the fifth metal layer 24CF may be formed together with other configurations of the semiconductor chip 1, and accordingly, the fourth metal layer 24C and the fifth metal layer 24CF may correspond to the other configurations of the semiconductor chip 1.

For example, the fourth metal layer 24C may be formed in the same process as the sub pad 24 and the fifth guide ring patterns 24G, and accordingly, the fourth metal layer 24C may correspond to the sub pad 24 and the fifth guide ring patterns 24G. Therefore, the fourth metal layer 24C may be at the same vertical level as the sub pad 24 and the fifth guide ring patterns 24G, may be formed of the same material, and may also have the same thickness.

The fifth metal layer 24CF may be formed in the same process as the sub pad metal layer 24F and the fifth guide ring pattern metal layer 24GF, and accordingly, the fifth metal layer 24CF may correspond to the sub pad metal layer 24F and the fifth guide ring pattern metal layer 24GF. Therefore, the fifth metal layer 24CF may be at the same vertical level as the sub pad metal layer 24F and the fifth guide ring pattern metal layer 24GF, may be formed of the same material, and may also have the same thickness.

The third metal structure M3 may be formed together with other configurations of the semiconductor chip 1, and accordingly, the third metal structure M3 may correspond to the other configurations of the semiconductor chip 1 based on the manufacturing process. For example, the third metal structure M3 may be formed in the same process as the second upper via patterns 32, and accordingly, the third metal structure M3 may correspond to the second upper via patterns 32. Therefore, the third metal structure M3 may be at the same vertical level as the second upper via patterns 32, may be formed of the same material, and may also have the same thickness.

The fourth metal structure M4 may include a sixth metal layer 31C and a seventh metal layer 31CF. Likewise, the sixth metal layer 31C and the seventh metal layer 31CF may be formed together with other components of the semiconductor chip 1, and based on the manufacturing process, the sixth metal layer 31C and the seventh metal layer 31CF may correspond to the other components of the semiconductor chip 1.

For example, the sixth metal layer 31C may be formed in the same process as the bonding pad 31P, and accordingly, the sixth metal layer 31C may correspond to the bonding pad 31P. Therefore, the sixth metal layer 31C may be at the same vertical level as the bonding pad 31P, may be formed of the same material, and may also have the same thickness.

The seventh metal layer 31CF may be formed in the same process as the bonding pad metal layer 31PF, and accordingly, the seventh metal layer 31CF may correspond to the bonding pad metal layer 31PF. Therefore, the seventh metal layer 31CF may be at the same vertical level as the bonding pad metal layer 31PF, may be formed of the same material, and may also have the same thickness.

As described above, the first metal structure M1 may have a form in which horizontal widths of the plurality of metal layers decrease in a direction away from the device interlayer insulating layer 13. A horizontal width of the second metal structure M2 may be less than a horizontal width of the third metal layer ML3 provided at the uppermost layer of the first metal structure M1. A horizontal width of the third metal structure M3 may be less than a horizontal width of the fifth metal layer 24CF provided at the uppermost layer of the second metal structure M2. A horizontal width of a lower surface of the fourth metal structure M4 may be less than a horizontal width of the third metal structure M3.

Individual shapes of the first, second, third, and fourth metal structures M1, M2, M3, and M4 may be determined according to the characteristics of a manufacturing process. For example, the sixth metal layer 31C of the fourth metal structure M4 may have a tapered shape in which a horizontal width of the sixth metal layer 31C decreases in a direction away from the device interlayer insulating layer 13.

Based on the device interlayer insulating layer 13, a vertical level of the uppermost portion of the first crack propagation prevention structure 60A may be higher than a vertical level of the lowermost portion of the first blocking trench TR1. Based on the device interlayer insulating layer 13, the vertical level of the uppermost portion of the first crack propagation prevention structure 60A may be higher than a vertical level of the lowermost portion of the second blocking trench TR2. The configurations of the vertical levels are to prevent a crack from propagating beyond the second blocking trench TR2 toward the device region DR by the first crack propagation prevention structure 60A, and also, a crack propagating beyond the first crack propagation prevention structure 60A toward the device region DR may be blocked by the first blocking trench TR1.

Referring to FIG. 4, a crack may propagate from the outside of the semiconductor chip 1 according to embodiments to the inside of the semiconductor chip 1. For example, a first crack CR1 may propagate from the outside of the semiconductor chip 1 toward the device region DR. As illustrated in FIG. 4, the first crack CR1 propagating to the second blocking trench TR2 may not propagate further due to the second blocking trench TR2.

A second crack CR2 may propagate from the outside of the semiconductor chip 1 toward the device region DR. As illustrated in FIG. 4, although the second crack CR2 passes through the second blocking trench TR2 to propagate toward the device region DR, the second crack CR2 may be blocked by the first crack propagation prevention structure 60A, and accordingly, the second crack CR2 may not propagate any more.

A third crack CR3 may propagate from the outside of the semiconductor chip 1 toward the device region DR. As illustrated in FIG. 4, although the third crack CR3 passes through the second blocking trench TR2 and the first crack propagation prevention structure 60A to propagate toward the device region DR, the third crack CR3 may be blocked by the first blocking trench TR1 because a vertical level of the uppermost portion of the first crack propagation prevention structure 60A is higher than vertical levels of the lowermost portions of the first blocking trench TR1 and the second blocking trench TR2, even when the third crack CR3 passes through the first crack propagation prevention structure 60A. Therefore, the third crack CR3 may not further propagate toward the device region DR after reaching the first blocking trench TR1.

As described above, the semiconductor chip 1 according to embodiments may include the first blocking trench TR1, the second blocking trench TR2, and the first crack propagation prevention structure 60A. Due to the first blocking trench TR1, the second blocking trench TR2, and the first crack propagation prevention structure 60A, a crack which occurs at an outer edge of the semiconductor chip 1 and propagates toward the device region DR, may not reach the device region DR. Therefore, the semiconductor chip 1 according to embodiments may improve the reliability of the semiconductor chip 1 by including the first blocking trench TR1, the second blocking trench TR2, and the first crack propagation prevention structure 60A.

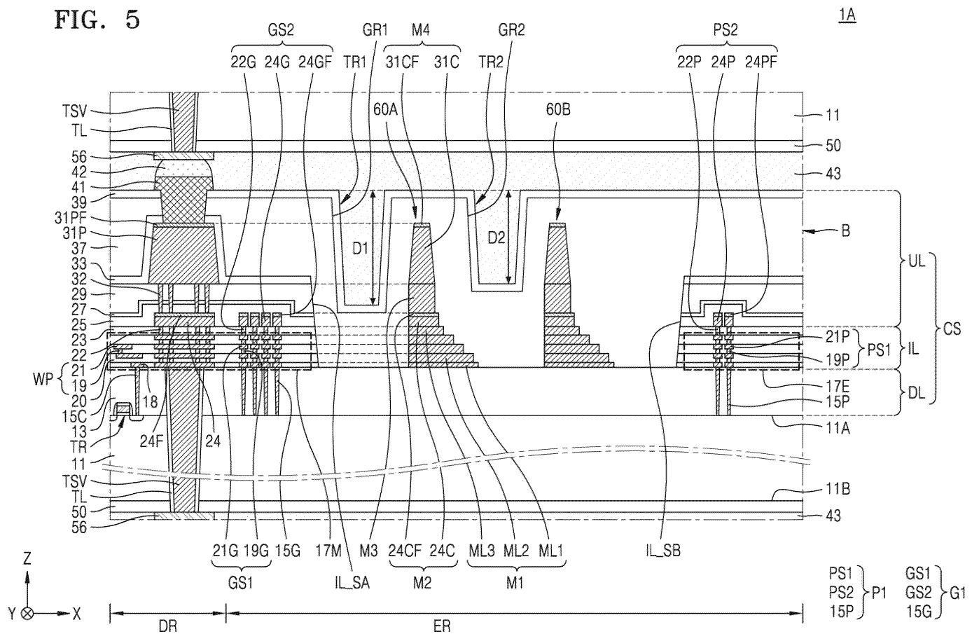

FIG. 5 is a cross-sectional view illustrating a semiconductor chip 1A according to an embodiment. In FIG. 5, like components with those of FIGS. 1-4 are indicated by like reference numbers and repeated descriptions thereof are omitted for conciseness. Descriptions not made below may be substantially the same as the descriptions given above.

Referring to FIG. 5, the semiconductor chip 1A may include a first substrate 11 and a circuit structure CS. The first substrate 11 may include a device region DR and an edge region ER surrounding the device region DR. The first substrate 11 may have a first surface 11A and a second surface 11B that are opposite to each other. The circuit structure CS may be on the first surface 11A of the first substrate 11. The circuit structure CS may include a device layer DL, a wiring layer IL, and an upper insulating stack UL that are sequentially stacked.

In a planar view, a first guide ring G1 may be on the outside of the device region DR to surround the device region DR. A first blocking trench TR1, a first crack propagation prevention structure 60A, a second blocking trench TR2, and a second crack propagation prevention structure 60B may sequentially surround the device region DR.

The first crack propagation prevention structure 60A and the second crack propagation prevention structure 60B may be provided between an inner lower insulating stack 17M and an outer lower insulating stack 17E. The first crack propagation prevention structure 60A and the second crack propagation prevention structure 60B may be provided on a device interlayer insulating layer 13, and the first crack propagation prevention structure 60A and the second crack propagation prevention structure 60B may each be surrounded by a sixth upper intermetal insulating layer 37.

The first crack propagation prevention structure 60A may be provided between the second blocking trench TR2 and the inner lower insulating stack 17M. The first crack propagation prevention structure 60A may be provided between the first blocking trench TR1 and the second blocking trench TR2. The second crack propagation prevention structure 60B may be provided between the first blocking trench TR1 and the outer lower insulating stack 17E. The second crack propagation prevention structure 60B may be provided between the second blocking trench TR2 and the outer lower insulating stack 17E.

A vertical level of the uppermost portion of the second crack propagation prevention structure 60B may be higher than a vertical level of the lowermost portion of the first blocking trench TR1 and a vertical level of the lowermost portion of the second blocking trench TR2. Due to this vertical level, although a crack may pass through the second crack propagation prevention structure 60B, the crack may be blocked by the second blocking trench TR2.

Similarly to the first crack propagation prevention structure 60A, the second crack propagation prevention structure 60B may include a first metal structure M1, a second metal structure M2, a third metal structure M3, and a fourth metal structure M4. The first metal structure M1 may include a plurality of stacked metal layers. For example, the first metal structure M1 may include a first metal layer ML1, a second metal layer ML2, and a third metal layer ML3.

The first metal structure M1, the second metal structure M2, the third metal structure M3, and the fourth metal structure M4 included in the second crack propagation prevention structure 60B may be formed together while other configurations of the semiconductor chip 1. That is, other configurations than the second crack propagation prevention structure 60B of the semiconductor chip 1A may be formed in the same manufacturing process as the first metal structure M1, the second metal structure M2, the third metal structure M3, and the fourth metal structure M4. Specific descriptions thereof may be substantially the same as the descriptions of the first crack propagation prevention structure 60A and thus are omitted for conciseness.

The semiconductor chip 1A may include the first blocking trench TR1, the second blocking trench TR2, the first crack propagation prevention structure 60A, and the second crack propagation prevention structure 60B. Through the configurations, a crack, which occurs at an outer edge of the semiconductor chip 1A and propagates toward the device region DR, may be prevented from reaching the device region DR, and thus, the reliability of the semiconductor chip 1A may be improved.

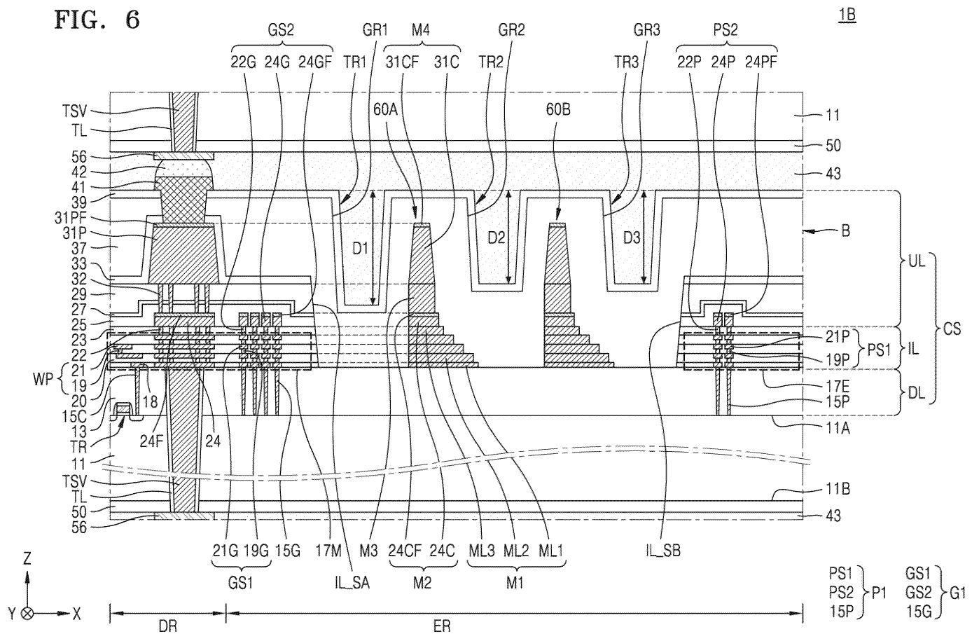

FIG. 6 is a cross-sectional view illustrating a semiconductor chip 1B according to an embodiment. In FIG. 6, like components with those of FIGS. 1-5 are indicated by like reference numbers and repeated descriptions thereof are omitted for conciseness. Descriptions not made below may be substantially the same as the descriptions given above.

Referring to FIG. 6, the semiconductor chip may include a first substrate 11 and a circuit structure CS. The first substrate 11 may include a device region DR and an edge region ER surrounding the device region DR. The first substrate 11 may have a first surface 11A and a second surface 11B that are opposite to each other. The circuit structure CS may be on the first surface 11A of the first substrate 11. The circuit structure CS may include a device layer DL, a wiring layer IL, and an upper insulating stack UL that are sequentially stacked.

In a planar view, a first guide ring G1 may be on the outside of the device region DR to surround the device region DR. A first blocking trench TR1, a first crack propagation prevention structure 60A, a second blocking trench TR2, a second crack propagation prevention structure 60B, and a third blocking trench TR3 may sequentially surround the device region DR.

A sixth upper intermetal insulating layer 37 may extend over a fifth upper intermetal insulating layer 33 and a device interlayer insulating layer 13 to be provided over the fifth upper intermetal insulating layer 33 and the device interlayer insulating layer 13. The sixth upper intermetal insulating layer 37 may include a first blocking groove GR1 and a second blocking groove GR2, each being formed as a groove in which a part of the sixth upper intermetal insulating layer 37 is recessed toward the first substrate 11. The sixth upper intermetal insulating layer 37 may include a third blocking groove GR3 formed as a groove in which a part of the sixth upper intermetal insulating layer 37 is recessed toward the first substrate 11. The third blocking groove GR3 may be provided between the second crack propagation prevention structure 60B and an outer lower insulating stack 17E.

An upper passivation layer 39 may be provided on an upper insulating stack UL. The upper passivation layer 39 may extend along a surface of the sixth upper intermetal insulating layer 37. That is, the upper passivation layer 39 may be substantially conformally provided along surfaces of the first blocking groove GR1, the second blocking groove GR2, and the third blocking groove GR3 formed in the sixth upper intermetal insulating layer 37. A groove formed by substantially uniformly providing the upper passivation layer 39 in the third blocking groove GR3 may be referred to as a third blocking trench TR3. A distance from an upper surface of the upper passivation layer 39 to the deepest surface of the groove of the third blocking trench TR3 may be referred to as a third depth D3.

A first depth D1 of the first blocking trench TR1, a second depth D2 of the second blocking trench TR2, and the third depth D3 of the third blocking trench TR3 may be less than a vertical level from the device interlayer insulating layer 13 to an upper surface of the upper passivation layer 39. The first depth D1 of the first blocking trench TR1 may be equal to or greater than the second depth D2 of the second blocking trench TR2. The second depth D2 of the second blocking trench TR2 may be equal to or greater than the third depth D3 of the third blocking trench TR3. Through a relationship between the first blocking trench TR1, the second blocking trench TR2, and the third blocking trench TR3, a crack propagating to the device region DR may be more effectively blocked.

The first blocking trench TR1, the second blocking trench TR2, and the third blocking trench TR3 may each have a tapered shape in which a horizontal width of the first blocking trench TR1, a horizontal width of the second blocking trench TR2, and a horizontal width of the third blocking trench TR3 decrease toward the device interlayer insulating layer 13 or the first substrate 11.

The third blocking trench TR3 may be provided between the second crack propagation prevention structure 60B and the outer lower insulating stack 17E. Based on the device interlayer insulating layer 13, a vertical level of the uppermost portion of the first crack propagation prevention structure 60A may be higher than a vertical level of the lowermost portion of the first blocking trench TR1, a vertical level of the lowermost portion of the second blocking trench TR2, and a vertical level of the lowermost portion of the third blocking trench TR3. Based on the device interlayer insulating layer 13, a vertical level of the uppermost portion of the second crack propagation prevention structure 60B may be higher than the vertical level of the lowermost portion of the first blocking trench TR1, the vertical level of the lowermost portion of the second blocking trench TR2, and the vertical level of the lowermost portion of the third blocking trench TR3.

The semiconductor chip 1B may include the first blocking trench TR1, the second blocking trench TR2, the third blocking trench TR3, the first crack propagation prevention structure 60A, and the second crack propagation prevention structure 60B. Through the configurations, a crack, which occurs at an outer edge of the semiconductor chip 1B and propagates toward the device region DR, may be prevented from reaching the device region DR, and thus, the reliability of the semiconductor chip 1B may be improved.

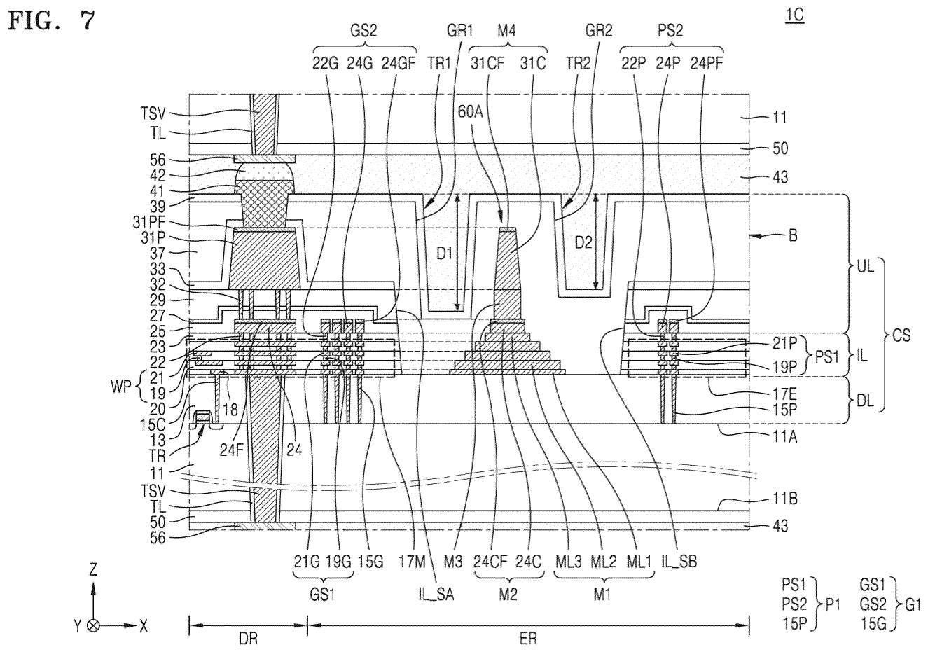

FIG. 7 is a cross-sectional view illustrating a semiconductor chip 1C according to an embodiment. In FIG. 7, like components with those of FIGS. 1-6 are indicated by like reference numbers and repeated descriptions thereof are omitted for conciseness. Descriptions not made below may be substantially the same as the descriptions given above.

Referring to FIG. 7, the semiconductor chip 1C may include a first substrate 11 and a circuit structure CS. The first substrate 11 may include a device region DR and an edge region ER surrounding the device region DR. The first substrate 11 may have a first surface 11A and a second surface 11B that are opposite to each other. The circuit structure CS may be on the first surface 11A of the first substrate 11. The circuit structure CS may include a device layer DL, a wiring layer IL, and an upper insulating stack UL that are sequentially stacked.

A first crack propagation prevention structure 60A may include a first metal structure M1, a second metal structure M2, a third metal structure M3, and a fourth metal structure M4. The first metal structure M1 may include a plurality of stacked metal layers. For example, the first metal structure M1 may include a first metal layer ML1, a second metal layer ML2, and a third metal layer ML3.

Horizontal widths of the plurality of metal layers included in the first metal structure M1 may decrease in a direction away from a device interlayer insulating layer 13. That is, the entire cross-sectional shape of the first metal structure M1 may be a kind of trapezoidal shape. The first metal structure M1 may have structural stability through the cross-sectional shape described above.

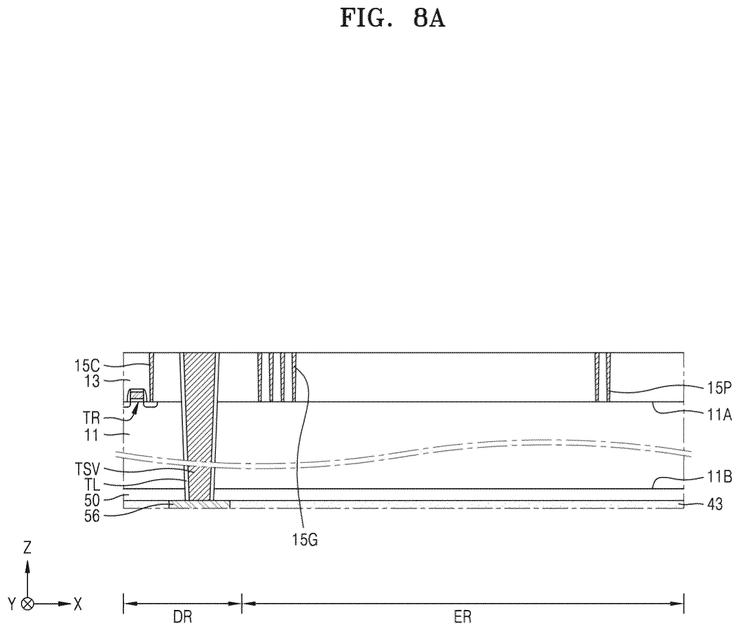

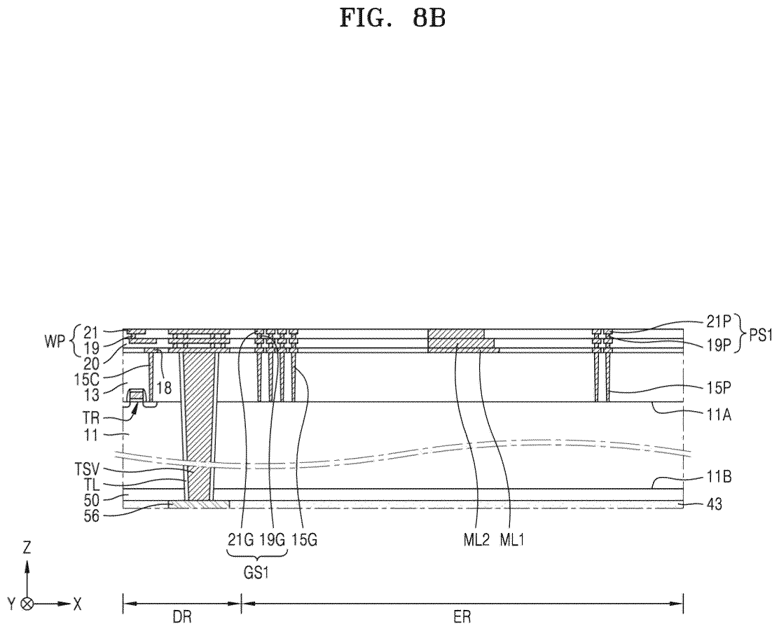

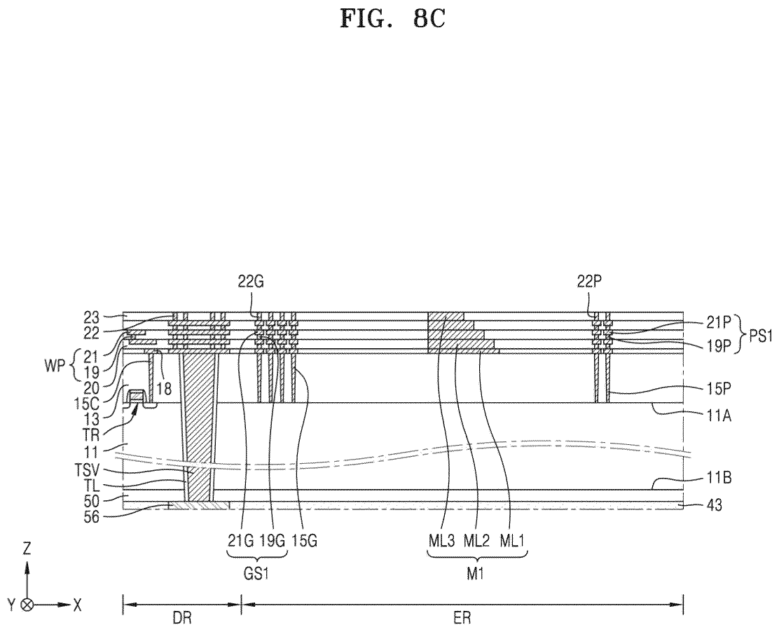

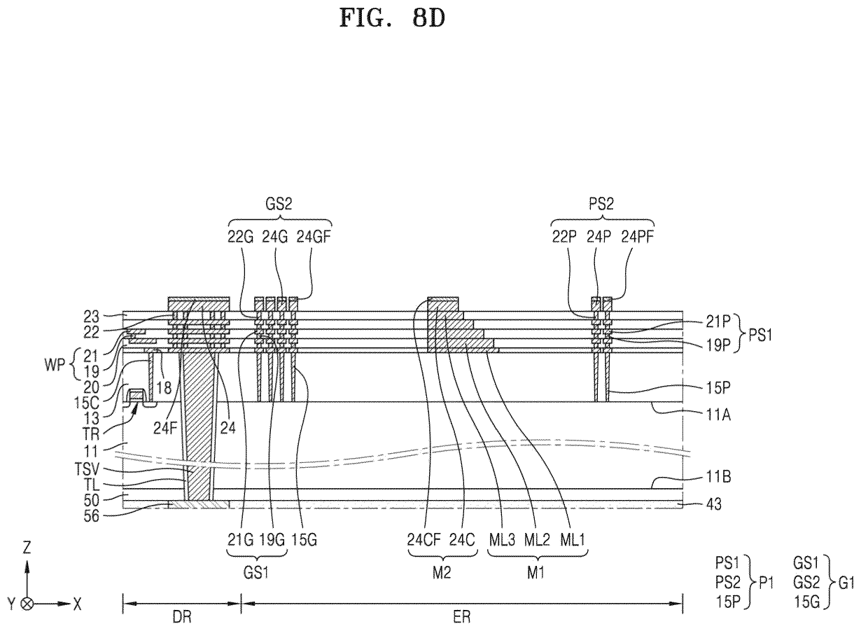

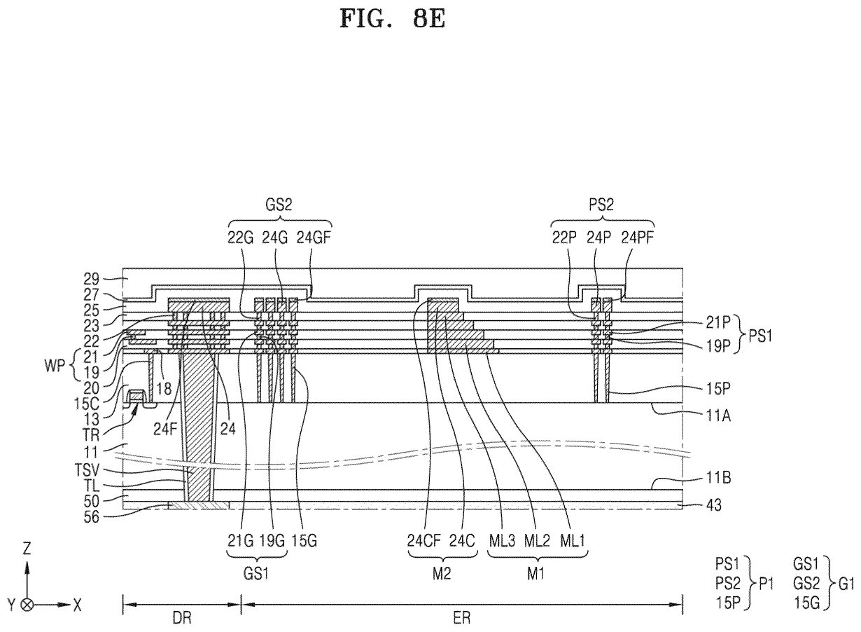

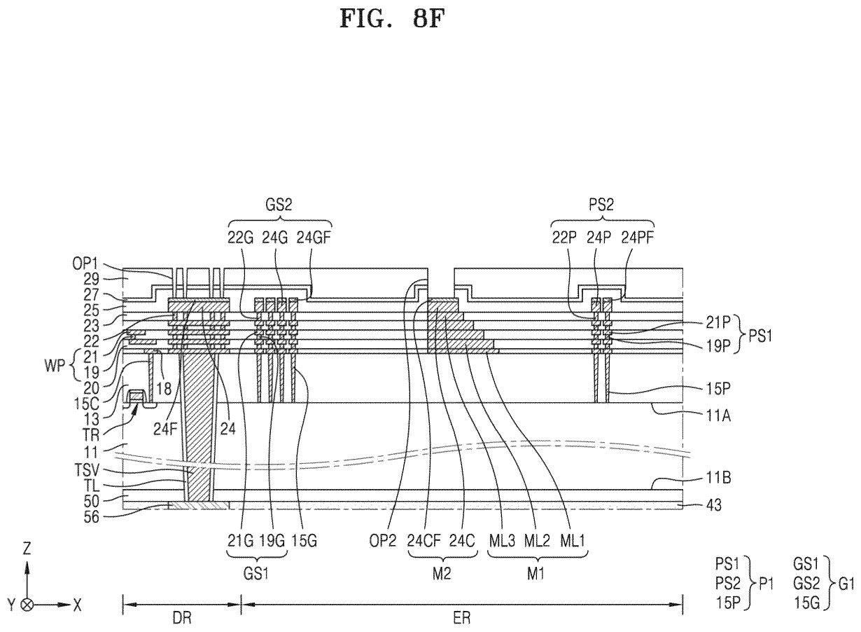

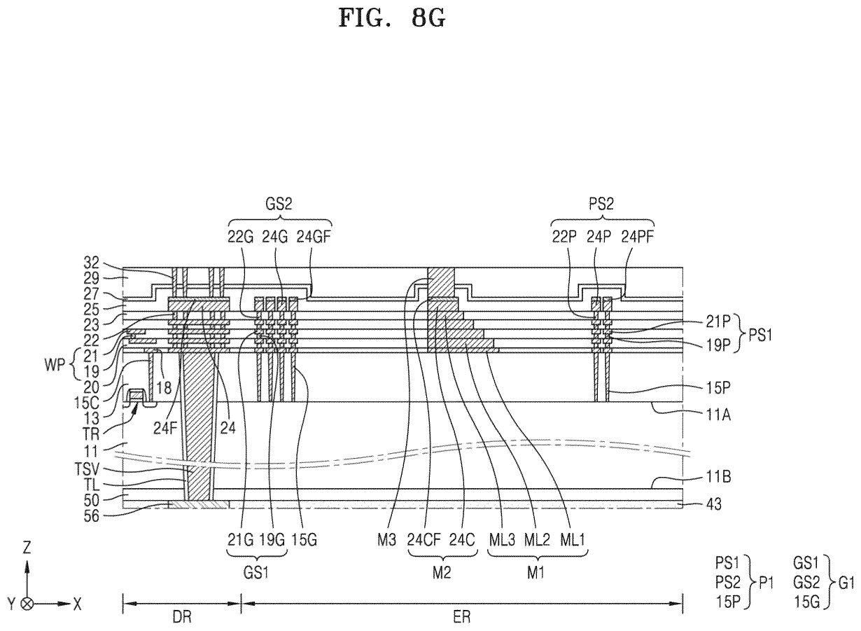

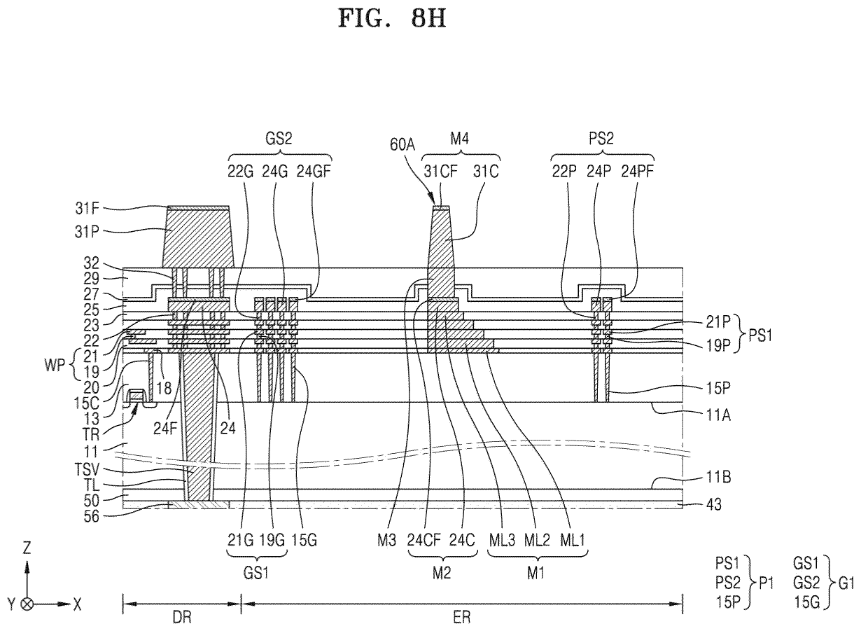

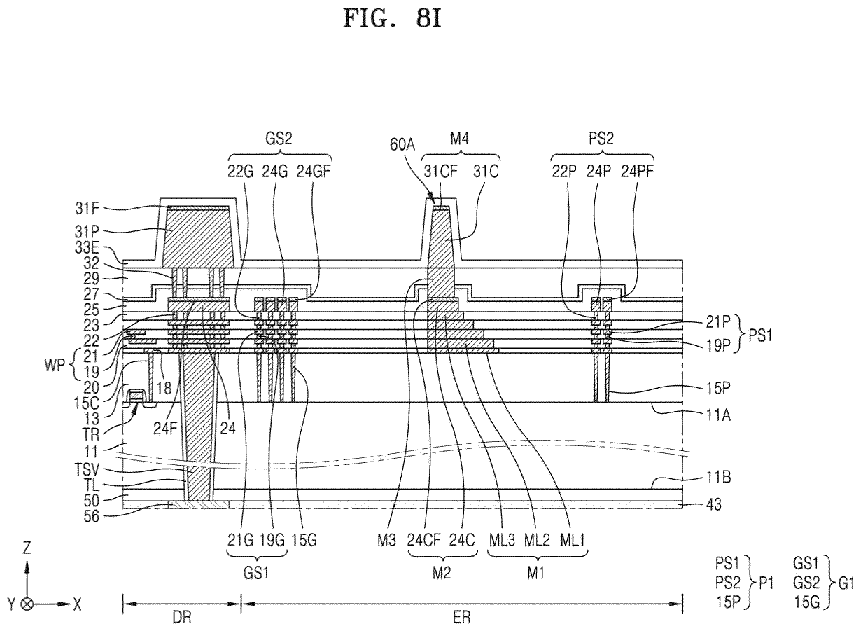

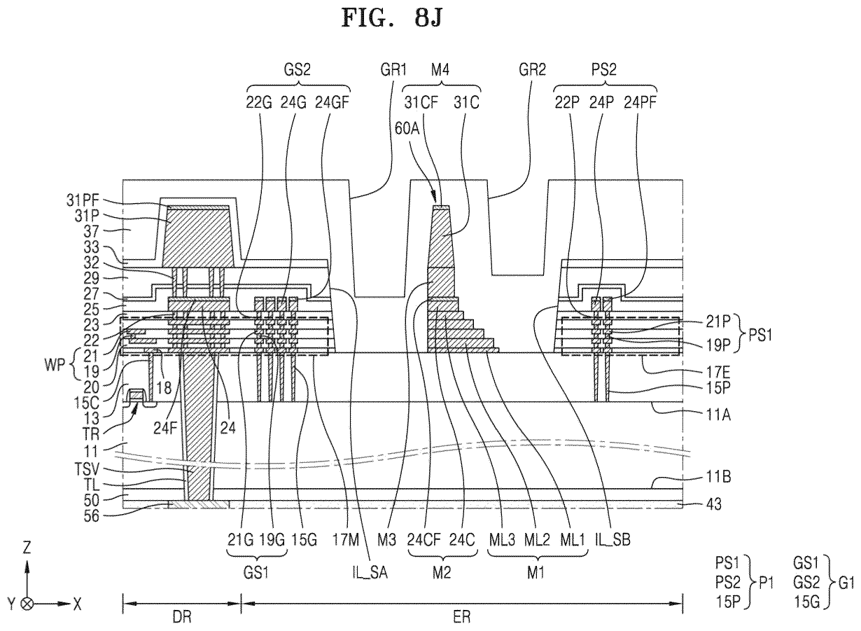

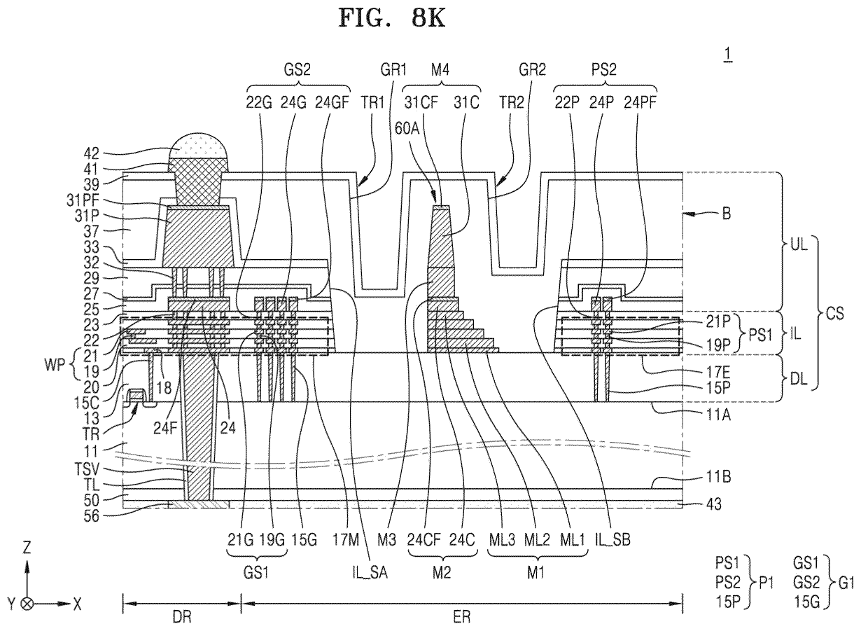

FIGS. 8A to 8K are cross-sectional views sequentially illustrating a manufacturing process of a semiconductor chip 1, according to embodiments. In FIGS. 8A to 8K, like components with those of FIGS. 1-7 are indicated by like reference numbers and repeated descriptions thereof are omitted for conciseness. Descriptions not made below may be substantially the same as the descriptions given above.

Referring to FIG. 8A, memory devices, such as device separation patterns, memory cells, and capacitors, may be provided in a device region DR of a first substrate 11. For example, transistors TR may be provided in the device region DR of the first substrate 11. The memory devices including the transistors TR, and the first surface 11A of the first substrate 11 may be covered by a device interlayer insulating layer 13. Thereafter, contact plugs 15C, first guide ring patterns 15G, and first chipping dams 15P may be formed in the device interlayer insulating layer 13. A process of forming metallic structures, such as the contact plugs 15C, the first guide ring patterns 15G, and the first chipping dams 15P, may include processes of patterning, etching, and deposition using a photoresist.

Referring to FIG. 8B, lower intermetal insulating layers 20 may be formed on the device interlayer insulating layer 13. While the lower metal interlayer insulating layers 20 are formed one by one, lower line patterns 21 and lower via patterns 19 may be formed.

Lowermost lower line patterns 18 provided directly on the device interlayer insulating layer 13, second guide patterns 21G provided directly above the device interlayer insulating layer 13, second chipping dam patterns 21P provided directly above the device interlayer insulating layer 13, and a first metal layer ML1 may be formed in the same process. That is, the lowermost lower line patterns 18 that are provided directly on the interlayer insulating layer 13 and are at the same vertical level as the first metal layer ML1, the second guide patterns 21G provided directly above the device interlayer insulating layer 13, the second chipping dam patterns 21P provided directly above the device interlayer insulating layer 13, and the first metal layer ML1 may include the same material and may have substantially the same thickness.

Wiring patterns WP, the second guide ring patterns 21G, third guide ring patterns 19G formed integrally with the second guide ring patterns 21G, the second chipping dam patterns 21P, third chipping dam patterns 19P formed integrally with the second chipping dam patterns 21P, and a second metal layer ML2 may be formed in the same process. That is, the wiring patterns WP at the same vertical level as the second metal layer ML2, the second guide ring patterns 21G, the third guide ring patterns 19G formed integrally with the second guide ring patterns 21G, the second chipping dam patterns 21P, and the third chipping dam patterns 19P formed integrally with the second chipping dam patterns 21P may include the same material and may have substantially the same thickness.

The wiring patterns WP may be formed integrally with lower via patterns 19 directly connected to the lower line patterns 21 during a manufacturing process. For example, the lower line patterns 21 and the lower via patterns 19 formed integrally with the lower line patterns 21 may be formed integrally through a single deposition process.

Referring to FIG. 8C, during a process of forming the lower intermetal insulating layers 20, the lower line patterns 21, the lower via patterns 19, and first upper via patterns 22 may be formed sequentially.

The first upper via patterns 22, fourth guide ring patterns 22G provided at the same vertical level as the first upper via patterns 22, fourth chipping dam patterns 22P provided at the same vertical level as the first upper via patterns 22, and a third metal layer ML3 may be formed in the same process. That is, the first upper via patterns 22 provided at the same vertical level as the third metal layer ML3, the fourth guiding patterns 22G provided at the same vertical level as the first upper via patterns 22, and the fourth chipping dam patterns 22P provided at the same vertical level as the first upper via patterns 22 may include the same material and may have substantially the same thickness.

Referring to FIG. 8D, a sub pad 24 and a sub pad metal layer 24F may be formed on the lower intermetal insulating layers 20 and above the first upper intermetal insulating layer 23. The sub pad 24 may be formed above the first upper via patterns 22 and may be electrically connected to the first upper via patterns 22. In the process of forming the sub pad 24, fifth guide ring patterns 24G, fifth chipping dam patterns 24P, and fourth metal layer 24C may be formed together. Therefore, the sub pad 24, the fifth guide ring patterns 24G, the fifth chipping dam patterns 24P, and the fourth metal layer 24C may include the same material, may have substantially the same thickness, or may be at the same vertical level.

In the process of forming the sub pad metal layer 24F, fifth guide pattern metal layer 24GF, fifth chipping dam pattern metal layer 24PF, and fifth metal layer 24CF may be formed together. Therefore, the sub pad metal layer 24F, the fifth guide ring pattern metal layer 24GF, the fifth chipping dam pattern metal layer 24PF, and the fifth metal layer 24CF may include the same material, may have substantially the same thickness, or may be at the same vertical level.

Referring to FIG. 8E, a second upper intermetal insulating layer 25 may be formed above the lower intermetal insulating layers 20 to surround the sub pad 24, the fifth guide ring patterns 24G, the fifth chipping dam patterns 24P, the fourth metal layer 24C, the sub pad metal layer 24F, the fifth guide ring pattern metal layer 24GF, the fifth chipping dam pattern metal layer 24PF, and the fifth metal layer 24CF. The second upper intermetal insulating layer 25 may be formed with a substantially uniform thickness over the sub pad 24, the fifth guide ring patterns 24G, the fifth chipping dam patterns 24P, the fourth metal layer 24C, the sub pad metal layer 24F, the fifth guide ring pattern metal layer 24GF, the fifth chipping dam pattern metal layer 24PF, the fifth metal layer 24CF, and the first upper intermetal insulating layer 23.

A third upper intermetal insulating layer 27 may be formed on the second upper intermetal insulating layer 25. The third upper intermetal insulating layer 27 may be formed on the second upper intermetal insulating layer 25 to have a substantially uniform thickness along a surface shape of the second upper intermetal insulating layer 25. Thereafter, a fourth upper intermetal insulating layer 29 may be formed with a substantially uniform thickness along a surface shape of the third upper intermetal insulating layer 27. The fourth upper intermetal insulating layer 29 may be planarized through chemical-mechanical polishing (CMP).

Referring to FIG. 8F, a plurality of first openings OP1 and a second opening OP2 may be formed to penetrate the fourth upper intermetal insulating layer 29, the third upper intermetal insulating layer 27, and at least part of the second upper intermetal insulating layer 25 of FIG. 8E. The plurality of first openings OP1 and the second opening OP2 may be formed through an etching process after being patterned through exposure. A part of an upper surface of the sub pad metal layer 24F may be exposed to the outside through the plurality of first openings OP1, and at least part of an upper surface of the fifth metal layer 24CF may be exposed to the outside through the second opening OP2.

Referring to FIG. 8G, second upper via patterns 32 may be respectively formed in the plurality of first openings OP1 of FIG. 8E, and a third metal structure M3 may be formed in the second opening OP2. For example, a horizontal width of the third metal structure M3 may be equal to or less than a horizontal width of the second metal structure M2 provided below the third metal structure M3.

Referring to FIG. 8H, a bonding pad 31P and a fourth metal structure M4 may be formed on the fourth upper intermetal insulating layer 29. The bonding pad 31P may be formed on the second upper via patterns 32 to be electrically connected to the second upper via patterns 32. The fourth metal structure M4 may be formed on the third metal structure M3. The fourth metal structure M4 may include a sixth metal layer 31C and a seventh metal layer 31CF, and a bonding pad metal layer 31PF on the bonding pad 31P may be formed together with the seventh metal layer 31CF.

Because the bonding pad 31P and the sixth metal layer 31C are formed in the same process, the bonding pad 31P and the sixth metal layer 31C may include the same material, may have substantially the same thickness, and may be at the same vertical level. Because the bonding pad metal layer 31PF and the seventh metal layer 31CF are formed in the same process, the bonding pad metal layer 31PF and the seventh metal layer 31CF may include the same material, may have substantially the same thickness, and may be at the same vertical level.

Referring to FIG. 8I, a fifth upper intermetal insulating layer 33 may substantially uniformly cover the bonding pad 31P, the bonding pad metal layer 31PF, and surfaces of the fourth metal structure M4 and the fourth upper intermetal insulating layer 29.

Referring to FIG. 8J, after patterning is performed through exposure on the fifth upper intermetal insulating layer 33, a part of each of the lower intermetal insulating layers 20 adjacent to the first crack propagation prevention structure 60A and a part of each of first, second, third, fourth, and fifth upper intermetal insulating layers 23, 25, 27, 29, and 33 adjacent to the first crack propagation prevention structure 60A may be removed through an etching process.

A first insulating layer side surface IL_SA, which is a surface in which the first, second, third, fourth, and fifth upper intermetal insulating layers 23, 25, 27, 29, and 33 and the lower intermetal insulating layers 20 face the first crack propagation prevention structure 60A, faces one surface of the first crack propagation prevention structure 60A, and the first insulating layer side surface IL_SA may be separated from the first crack propagation prevention structure 60A. A second insulating layer side surface IL_SB, which is a surface in which the first, second, third, fourth, and fifth upper intermetal insulating layers 23, 25, 27, 29, and 33 and the lower intermetal insulating layers 20 face the first crack propagation prevention structure 60A, faces one surface of the first crack propagation prevention structure 60A, and the second insulating layer side surface IL_SB may be separated from the first crack propagation prevention structure 60A. The first insulating layer side surface IL_SA may be separated from the second insulating layer side surface IL_SB, and the first crack propagation prevention structure 60A may be provided between the first insulating layer side surface IL_SA and the second insulating layer side surface IL_SB.

Thereafter, a sixth upper intermetal insulating layer 37 may be formed along surfaces of the fifth upper intermetal insulating layer 33, the first insulating layer side surface IL_SA, the device interlayer insulating layer 13, the first crack propagation prevention structure 60A, and the second insulating layer side surface IL_SB. The sixth upper intermetal insulating layer 37 may have a substantially uniform thickness.

While the sixth upper intermetal insulating layer 37 is formed between the first insulating layer side surface IL_SA and the first crack propagation prevention structure 60A, a first blocking groove GR1 may be formed due to a distance between the first insulating layer side surface IL_SA and the first crack propagation prevention structure 60A. While the sixth upper intermetal insulating layer 37 is formed between the second insulating layer side surface IL_SB and the first crack propagation prevention structure 60A, a second blocking groove GR2 may be formed due to a distance between the second insulating layer side surface IL_SB and the first crack propagation prevention structure 60A.

Thereafter, a part of the sixth upper intermetal insulating layer 37 may be removed through CMP.

Referring to FIG. 8K, an upper passivation layer 39 may be formed on the sixth upper intermetal insulating layer 37 and may have a substantially uniform thickness. A third opening may be formed by penetrating the upper passivation layer 39, the sixth upper intermetal insulating layer 37, and the fifth upper intermetal insulating layer 33, and then a conductive bump 41 may be formed in the third opening. A connection terminal 42 may be provided on the conductive bump 41, and accordingly, a semiconductor chip 1 according to an embodiment may be manufactured.

As described above, embodiments are described with reference to the attached drawings, and those skilled in the art to which the present disclosure belongs will understand that the various embodiments described herein may be modified into other specific forms without changing the technical idea or essential features. Therefore, the various embodiments described above are illustrative in all respects and should not be understood as limiting.

While the various embodiments have been particularly illustrated and described with reference to drawings, it will be understood that various changes in form and details may be made therein without departing from the spirit and scope of the following claims.

What is claimed is:

1. A semiconductor chip comprising:
a substrate including a device region and an edge region;
a device layer on the substrate, the device layer including a device interlayer insulating layer in the device layer;
a wiring layer on the device interlayer insulating layer and including an inner lower insulating stack and an outer lower insulating stack;
an upper insulating stack on the wiring layer and including a plurality of upper insulating layers;
a first crack propagation prevention structure on the device interlayer insulating layer between a first insulating layer side surface and a second insulating layer side surface, the first insulating layer side surface facing the inner lower insulating stack and the first crack propagation prevention structure and being at least partially included in the upper insulating stack, the second insulating layer side surface facing the outer lower insulating stack and the first crack propagation prevention structure and being at least partially included in the upper insulating stack; and
a first blocking trench between the first crack propagation prevention structure and the first insulating layer side surface, the first blocking trench being recessed from an upper surface of the upper insulating stack in a direction toward the substrate.

2. The semiconductor chip of claim 1, wherein a vertical level of a lowermost portion of the first blocking trench is lower than a vertical level of an uppermost portion of the first crack propagation prevention structure.

3. The semiconductor chip of claim 1, further comprising:
lower line patterns in the inner lower insulating stack;
lower via patterns in the inner lower insulating stack; and
sub pads above the lower via patterns and the lower line patterns,
wherein the first crack propagation prevention structure comprises a plurality of stacked metal structures, and
at least a portion of the plurality of stacked metal structures correspond respectively to the lower line patterns, the lower via patterns, and the sub pads, and are at same vertical levels, respectively, as the lower line patterns, the lower via patterns, and the sub pads.

4. The semiconductor chip of claim 1, further comprising:
a bonding pad at least partially buried in the upper insulating stack; and
upper via patterns electrically connecting the bonding pad and the wiring layer,
wherein the first crack propagation prevention structure comprises a plurality of stacked metal structures, and
at least a portion of the plurality of stacked metal structures respectively correspond to the bonding pad and the upper via patterns and are, respectively, at the same vertical levels as the bonding pad and the upper via patterns.

5. The semiconductor chip of claim 1, further comprising:
wiring patterns in the inner lower insulating stack, the wiring patterns including lower line patterns and lower via patterns;
a sub pad above the lower via patterns and the lower line patterns; and
a guide ring in the inner lower insulating stack between the first crack propagation prevention structure and the wiring patterns.

6. The semiconductor chip of claim 1, wherein:
the first crack propagation prevention structure includes a plurality of stacked metal structures, and
each of the plurality of stacked metal structures has a horizontal width decreasing in a direction away from the substrate.

7. The semiconductor chip of claim 1, wherein a vertical level of a lower surface of the first crack propagation prevention structure is equal to vertical levels of lowermost surfaces of the inner lower insulating stack and the outer lower insulating stack.

8. The semiconductor chip of claim 1, wherein:
the plurality of upper insulating layers include a sixth upper insulating layer between the first insulating layer side surface and the first crack propagation prevention structure, and between the second insulating layer side surface and the first crack propagation prevention structure, and
the sixth upper insulating layer is in contact with the device interlayer insulating layer.

9. The semiconductor chip of claim 1, further comprising:
wiring patterns in the inner lower insulating stack, the wiring patterns including lower line patterns and lower via patterns;
a sub pad above the lower via patterns and the lower line patterns;
a bonding pad at least partially buried in the upper insulating stack; and
upper via patterns electrically connecting the bonding pad to the sub pad,
wherein the first crack propagation prevention structure includes a first metal structure, a second metal structure, a third metal structure, and a fourth metal structure, and
the first metal structure includes a plurality of metal layers.

10. The semiconductor chip of claim 9, wherein:
vertical levels of at least a portion of the plurality of metal layers of the first metal structure are equal to vertical levels of the wiring patterns that correspond, respectively, to the at least a portion of the plurality of metal layers, and
a vertical level of the second metal structure is equal to a vertical level of the sub pad that corresponds to the second metal structure.

11. The semiconductor chip of claim 10, wherein the at least a portion of the plurality of metal layers and the wiring patterns corresponding to the at least a portion of the plurality of metal layers include a same material and have a same thickness.

12. The semiconductor chip of claim 9, wherein:
a vertical level of the third metal structure is equal to a vertical level of the upper via patterns that correspond to the third metal structure, and a vertical level of the fourth metal structure is equal to a vertical level of the bonding pad that correspond to the fourth metal structure,
the third metal structure and the upper via patterns that correspond to the third metal structure include a same material and have a same thickness, and
the fourth metal structure and the bonding pad that correspond to the fourth metal structure include a same material and have a same thickness.

13. The semiconductor chip of claim 1, further comprising:
a second blocking trench between the first crack propagation prevention structure and the second insulating layer side surface, the second blocking trench being recessed from the upper surface of the upper insulating stack toward the substrate,
wherein a vertical level of a lowermost portion of the second blocking trench is lower than a vertical level of an uppermost portion of the first crack propagation prevention structure.

14. The semiconductor chip of claim 13, wherein a first depth of the first blocking trench from the upper surface of the upper insulating stack is equal to or greater than a second depth of the second blocking trench from the upper surface of the upper insulating stack.

15. The semiconductor chip of claim 13, further comprising:
a second crack propagation prevention structure on the device interlayer insulating layer between the second blocking trench and the second insulating layer side surface,
wherein a vertical level of an uppermost portion of the second crack propagation prevention structure is higher than a vertical level of the lowermost portion of the second blocking trench.

16. A semiconductor chip comprising:
a substrate including a device region and an edge region;
a device layer provided on the substrate, the device layer including a device interlayer insulating layer in the device layer;
a wiring layer on the device interlayer insulating layer, the wiring layer including an inner lower insulating stack and an outer lower insulating stack;
an upper insulating stack on the wiring layer, the upper insulating stack including a plurality of upper insulating layers;
a first crack propagation prevention structure between the inner lower insulating stack and the outer lower insulating stack; and
a first blocking trench between the first crack propagation prevention structure and the inner lower insulating stack, the first blocking trench being recessed from an upper surface of the upper insulating stack toward the substrate,
wherein the first blocking trench surrounds the device region in a planar view, and
the first crack propagation prevention structure surrounds the first blocking trench and the device region in a planar view.

17. The semiconductor chip of claim 16, wherein a vertical level of a lowermost portion of the first blocking trench is lower than a vertical level of an uppermost portion of the first crack propagation prevention structure.

18. The semiconductor chip of claim 16, further comprising:
a second blocking trench between the first crack propagation prevention structure and the outer lower insulating stack, the second blocking trench being recessed from the upper surface of the upper insulating stack toward the substrate,
wherein a vertical level of a lowermost portion of the second blocking trench is lower than a vertical level of an uppermost portion of the first crack propagation prevention structure.

19. The semiconductor chip of claim 18, wherein a first depth of the first blocking trench from the upper surface of the upper insulating stack is equal to or greater than a second depth of the second blocking trench from the upper surface of the upper insulating stack.

20. A semiconductor chip comprising:
a substrate including a device region and an edge region;
a device layer provided on the substrate, the device layer including a device interlayer insulating layer in the device layer;
a wiring layer on the device interlayer insulating layer, the wiring layer including an inner lower insulating stack and an outer lower insulating stack;
an upper insulating stack on the wiring layer, the upper insulating stack including a plurality of upper insulating layers;
a first crack propagation prevention structure on the device interlayer insulating layer between a first insulating layer side surface and a second insulating layer side surface, the first insulating layer side surface facing the inner lower insulating stack and the first crack propagation prevention structure and being at least partially included in the upper insulating stack, and the second insulating layer side surface facing the outer lower insulating stack and the first crack propagation prevention structure and being at least partially included in the upper insulating stack;
a first blocking trench between the first crack propagation prevention structure and the first insulating layer side surface, the first blocking trench being recessed from an upper surface of the upper insulating stack in a direction toward the substrate;
a second blocking trench between the first crack propagation prevention structure and the second insulating layer side surface, the second blocking trench being recessed from the upper surface of the upper insulating stack toward the substrate;
wiring patterns in the inner lower insulating stack, the wiring patterns including lower line patterns and lower via patterns;
a sub pad above the lower via patterns and the lower line patterns;
a bonding pad at least partially buried in the upper insulating stack; and
upper via patterns electrically connecting the bonding pad to the sub pad,
wherein:
a first depth of the first blocking trench from the upper surface of the upper insulating stack toward the substrate is equal to or greater than a second depth of the second blocking trench from the upper surface of the upper insulating stack toward the substrate,
a vertical level of a lowermost portion of the first blocking trench and a vertical level of a lowermost portion of the second blocking trench are lower than a vertical level of an uppermost portion of the first crack propagation prevention structure,
the plurality of upper insulating layers include a sixth upper insulating layer between the first insulating layer side surface and the first crack propagation prevention structure, and between the second insulating layer side surface and the first crack propagation prevention structure,
the first blocking trench is between the first insulating layer side surface and the first crack propagation prevention structure,
the first crack propagation prevention structure includes a plurality of metal layers,
the plurality of metal layers correspond to the wiring patterns, the sub pad, the upper via patterns, and the bonding pad, which are respectively located at same vertical levels as the corresponding ones of the plurality of metal layers, and
the plurality of metal layers include a same material and have a same thickness as the wiring patterns, the sub pad, the upper via patterns, and the bonding pad, which respectively correspond to the plurality of metal layers.
